(19) United States
(12) Patent Application Publication
(10) Pub. No.: US 2025/0393209 A1
(43) Pub. Date: Dec. 25, 2025

(54) SEMICONDUCTOR MEMORY DEVICE

(71) Applicant: Kioxia Corporation, Tokyo (JP)

(72) Inventor: Daisuke KAWAMURA, Kiyosu Aichi (JP)

(73) Assignee: Kioxia Corporation, Tokyo (JP)

(21) Appl. No.: 18/977,719

(22) Filed: Dec. 11, 2024

(30) Foreign Application Priority Data
Jun. 20, 2024 (JP) 2024-099810

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

According to one embodiment, a semiconductor memory device includes a stacked body in which a plurality of conductive layers are stacked apart from each other, and first and second staircase regions in which the plurality of conductive layers are processed in a staircase shape are disposed at both end portions in a first direction intersecting a stacking direction of the plurality of conductive layers with a memory region interposed therebetween; a first plate-like portion that extends in the stacked body in the first direction and the stacking direction and divides the memory region into first and second sub-memory regions adjacent in a second direction intersecting both the stacking direction and the first direction; and a second plate-like portion that extends in the stacked body in the second direction and the stacking direction and divides the first sub-memory region and the first staircase region, in which the second plate-like portion is coupled to a side surface of the first plate-like portion in the second direction via an insulating metal element-containing layer.

### CROSS-REFERENCE TO RELATED APPLICATIONS

This application is based upon and claims the benefit of priority from Japanese Patent Application No. 2024-099810, filed on Jun. 20, 2024; the entire contents of which are incorporated herein by reference.

### FIELD

Embodiments described herein relate generally to a semiconductor memory device.

### BACKGROUND

In a semiconductor memory device such as a three-dimensional nonvolatile memory, memory cells are three-dimensionally disposed in a stacked body in which a plurality of conductive layers are stacked one by one while being apart from each other. These conductive layers are drawn out by being processed in a staircase shape in an end region or the like of the stacked body. As the number of stacked conductive layers increases, an area occupied by a region where the conductive layers are processed in a staircase shape also increases in the semiconductor memory device.

### BRIEF DESCRIPTION OF THE DRAWINGS

FIGS. 1A and 1B are diagrams illustrating a schematic configuration example of a semiconductor memory device according to an embodiment;

FIG. 2 is an XY cross-sectional diagram illustrating an example of a detailed layout of the semiconductor memory device according to the embodiment;

FIG. 3 is a schematic perspective diagram of a staircase region included on one side in an X direction in a stacked body of the semiconductor memory device according to the embodiment;

FIGS. 4A to 4G are cross-sectional diagrams illustrating an example of a configuration of the semiconductor memory device according to the embodiment;

FIGS. 5A to 5C are cross-sectional diagrams illustrating an example of a configuration of the semiconductor memory device according to the embodiment;

FIGS. 6A to 6E are cross-sectional diagrams sequentially illustrating a part of a procedure of a method for manufacturing the semiconductor memory device according to the embodiment;

FIGS. 7A to 7C are cross-sectional diagrams sequentially illustrating a part of the procedure of the method for manufacturing the semiconductor memory device according to the embodiment;

FIGS. 8A to 8C are cross-sectional diagrams sequentially illustrating a part of the procedure of the method for manufacturing the semiconductor memory device according to the embodiment;

FIGS. 9A to 9C are cross-sectional diagrams sequentially illustrating a part of the procedure of the method for manufacturing the semiconductor memory device according to the embodiment;

FIGS. 10A to 10D are cross-sectional diagrams sequentially illustrating a part of the procedure of the method for manufacturing the semiconductor memory device according to the embodiment;

FIGS. 11A to 11D are cross-sectional diagrams sequentially illustrating a part of the procedure of the method for manufacturing the semiconductor memory device according to the embodiment;

FIGS. 12A to 12C are cross-sectional diagrams sequentially illustrating a part of the procedure of the method for manufacturing the semiconductor memory device according to the embodiment;

FIGS. 13Aa to 13 Db are cross-sectional diagrams sequentially illustrating a part of a procedure of word line replacement processing in the semiconductor memory device according to the embodiment;

FIGS. 14Aa to 14Db are cross-sectional diagrams sequentially illustrating a part of the procedure of the word line replacement processing in the semiconductor memory device according to the embodiment;

FIGS. 15Aa to 15Db are cross-sectional diagrams sequentially illustrating a part of the procedure of the word line replacement processing in the semiconductor memory device according to the embodiment;

FIGS. 16Aa to 16Db are cross-sectional diagrams sequentially illustrating a part of the procedure of the word line replacement processing in the semiconductor memory device according to the embodiment;

FIGS. 17A to 17C are cross-sectional diagrams sequentially illustrating a part of a procedure of a method for forming a plate-like portion in a semiconductor memory device according to a modification of the embodiment;

FIGS. 18A to 18C are cross-sectional diagrams sequentially illustrating a part of the procedure of the method for forming the plate-like portion in the semiconductor memory device according to the modification of the embodiment; and

FIG. 19 is a schematic perspective diagram of a

staircase region included on one side in the X direction in a stacked body of a semiconductor memory device according to another modification of the embodiment.

### DETAILED DESCRIPTION

In general, according to one embodiment, a semiconductor memory device includes: a stacked body in which a plurality of conductive layers are stacked apart from each other, and first and second staircase regions in which the plurality of conductive layers are processed in a staircase shape are respectively disposed at both end portions in a first direction intersecting a stacking direction of the plurality of conductive layers with a memory region interposed therebetween; a first plate-like portion that extends in the stacked body in the first direction and the stacking direction and divides the memory region into first and second sub-memory regions adjacent in a second direction intersecting both the stacking direction and the first direction; and a second plate-like portion that extends in the stacked body in the second direction and the stacking direction and divides the first sub-memory region and the first staircase region, in which the second plate-like portion is coupled to a side surface of the first plate-like portion in the second direction via an insulating metal element-containing layer.

Exemplary embodiment of the semiconductor memory device will be explained below in detail with reference to the accompanying drawings. Note that the present invention is not limited to the following embodiment. In addition, constituent elements in the following embodiment include those that can be easily assumed by those skilled in the art or those that are substantially the same.

### Overall Configuration Example of Semiconductor Memory Device

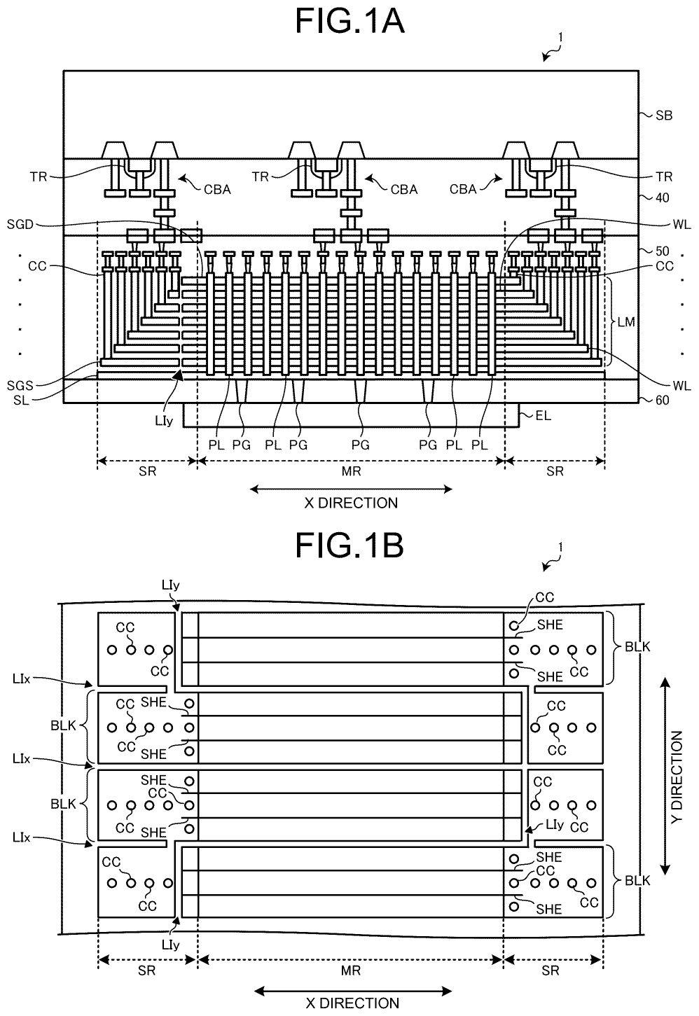

FIGS. 1A and 1B are diagrams illustrating a schematic configuration example of a semiconductor memory device 1 according to an embodiment. More specifically, FIG. 1A is a cross-sectional diagram of the semiconductor memory device 1 along an X direction, and FIG. 1B is a schematic plan diagram illustrating a layout of the semiconductor memory device 1.

However, in FIG. 1A, hatching is omitted in consideration of visibility of the drawing. In FIG. 1A, some upper layer wirings and the like are omitted.

In the present specification, both an X direction and a Y direction are directions along a direction of a surface of a word line WL, and the X direction and the Y direction are orthogonal to each other. In addition, an electrical drawing direction of the word line WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing variability, the first direction and the second direction are not necessarily orthogonal to each other.

As illustrated in FIG. 1A, the semiconductor memory device 1 includes a semiconductor substrate SB on which an electrode film EL, a source line SL, one or more select gate lines SGS, a plurality of word lines WL, one or more select gate lines SGD, and peripheral circuit CBA are provided in order from a lower side in the plane of drawing.

The source line SL is disposed on the electrode film EL via an insulating layer 60. A plurality of plugs PG are disposed in the insulating layer 60, and the source line SL and the electrode film EL maintain electrical conduction via the plugs PG. Although not illustrated, an electrode pad for supplying power and a signal from an outside to the semiconductor memory device 1 is provided in the same layer as the electrode film EL. Above the source line SL, the select gate line SGS, the plurality of word lines WL, and the select gate line SGD are stacked in this order to form a stacked body LM.

As illustrated in FIGS. 1A and 1B, a memory region MR is disposed at a central portion in the X direction of the stacked body LM, and staircase regions SR are respectively disposed at both end portions in the X direction of the stacked body LM. These staircase regions SR are regions used as lead-out portions of the plurality of word lines WL and the select gate lines SGD and SGS in the stacked body LM in order to electrically couple the plurality of word lines WL and the select gate lines SGD and SGS to the peripheral circuit CBA via contacts CC to be described later. The memory region MR and the staircase regions SR are divided into a plurality of regions by a plurality of plate-like portions LIx penetrating the stacked body LM and extending in the direction along the X direction.

Note that a region disposed between the plate-like portions LIx adjacent in the Y direction and including the staircase regions SR and the memory region MR between them is referred to as a block region BLK, the staircase regions SR and the memory region MR aligning in the X direction. As will be described later, the memory region MR includes a plurality of memory cells that hold data in a nonvolatile manner, and the block region BLK is an erase unit of the data.

Here, in one block region BLK, a plate-like portion LIy extending in the direction along the Y direction is disposed on one of the staircase regions SR, thereby dividing the one staircase region SR and the memory region MR of the stacked body LM. When viewed on one side in the X direction, the plate-like portion LIy is disposed, for example, every two of the block regions BLK.

That is, in the example of FIG. 1B, when viewed in the staircase region SR on the right side in the plane of drawing, the plate-like portion LIy is not disposed in the block regions BLK at the uppermost portion and the lowermost portion in the plane of drawing, and in each of these block regions BLK, the memory region MR is electrically coupled to the staircase region SR on the right side in the plane of drawing.

On the other hand, in the second and third block regions BLK from the uppermost portion in the plane of drawing, the plate-like portions LIy extending in the direction along the Y direction in the staircase region SR on the right side in the plane of drawing are disposed. Therefore, in these block regions BLK, the memory regions MR are not electrically coupled to the staircase region SR on the right side in the plane of drawing.

However, the plate-like portion LIx that divides the first block region BLK at the uppermost portion and the second block region BLK in the plane of drawing has a gap on each side in the X direction of the stacked body LM, each gap being between the memory region MR side and one of the staircase regions SR side with the plate-like portion LIy interposed therebetween.

Therefore, the staircase region SR on the right side in the plane of drawing, which is arranged in the X direction with the memory region MR belonging to the second block region BLK with the plate-like portion LIy interposed therebetween, is electrically coupled to the memory region MR belonging to the first block region BLK at the uppermost portion in the plane of drawing. In addition, the staircase region SR on the left side in the plane of drawing, which is arranged in the X direction with the memory region MR belonging to the first block region BLK with the plate-like portion LIy interposed therebetween, is electrically coupled to the memory region MR belonging to the second block region BLK from the uppermost portion in the plane of drawing.

Similarly, the plate-like portion LIx that divides the fourth block region BLK at the lowermost portion and the third block region BLK in the plane of drawing has a gap, on each side in the X direction of the stacked body LM, each gap being between the memory region MR side and the one of the staircase regions SR side with the plate-like portion LIy interposed therebetween.

Therefore, the staircase region SR on the right side in the plane of drawing, which is arranged in the X direction with the memory region MR belonging to the third block region BLK with the plate-like portion LIy interposed therebetween, is electrically coupled to the memory region MR belonging to the block region BLK at the lowermost portion in the plane of drawing. In addition, the staircase region SR on the left side in the plane of drawing, which is arranged in the X direction with the memory region MR belonging to the fourth block region BLK at the lowermost portion in the plane of drawing with the plate-like portion LIy interposed therebetween, is electrically coupled to the memory region MR belonging to the third block region BLK from the uppermost portion in the plane of drawing.

Note that individual memory regions MR belonging to the plurality of block regions BLK are electrically separated from each other by the plate-like portion LIx and the plate-like portion LIy.

Between the plate-like portions LIx adjacent in the Y direction, a plurality of separation layers SHE extending in the direction along the X direction penetrating the select gate line SGD are disposed. The plurality of separation layers SHE extend in the direction along the X direction over the entire memory region MR and reach a part of the staircase regions SR at both end portions in the X direction.

In the memory region MR, a plurality of pillars PL penetrating the stacked body LM in the stacking direction are disposed. A lower end of the pillar PL reaches the source line SL. A plurality of memory cells are formed at intersections of the pillars PL and the word lines WL. As a result, the semiconductor memory device 1 is configured as, for example, a three-dimensional nonvolatile memory in which memory cells are three-dimensionally disposed in the memory region MR.

In the staircase region SR, the plurality of word lines WL and the select gate lines SGD and SGS configuring the stacked body LM are respectively processed and terminated in a staircase shape so as not to overlap with the upper conductive layer in the stacking direction. At this time, as a distance from the memory region MR increases in the X direction, terminal end portions of the plurality of word lines WL and the select gate lines SGD and SGS shift from the upper layer side to the lower layer side, so that height positions of respective terrace portions where the plurality of word lines WL and the select gate lines SGD and SGS are provided so as not to overlap the upper conductive layer in the stacking direction are lowered toward the source line SL side.

Note that the separation layers SHE extend from the memory region MR to a portion where the select gate line SGD, of the staircase region SR, is processed in a staircase shape. As a result, in one block region BLK, the select gate line SGD is separated into a plurality of regions. In other words, the separation layers SHE penetrate the portions above the plurality of word lines WL, so that these upper layer portions are partitioned into the pattern of the plurality of select gate lines SGD.

In addition, the above-described plate-like portion LIy is disposed in the terrace portion of the select gate line SGD of the staircase region SR.

Each of contacts CC coupled to the word lines WL and the select gate lines SGD and SGS of each layer is respectively disposed on the terrace portion of each step which include either of the plurality of word lines WL and the select gate lines SGD and SGS. In the word line WL and the select gate line SGS, one contact CC is coupled for each layer. In the select gate line SGD, one contact CC is coupled for each section separated by the separation layers SHE per layer.

Here, in one block region BLK, the contact CC coupled to the select gate line SGD is disposed on one side of the staircase regions SR on both sides in the X direction. In addition, when viewed in the staircase region SR on one side in the X direction, these contacts CC coupled to the select gate line SGD are disposed every two of the block regions BLK, for example.

That is, in the example of FIG. 1B, in each of the block regions BLK at the uppermost portion and the lowermost portion in the plane of drawing, one of the staircase regions SR on both sides in the X direction has the contacts CC coupled to the select gate line SGD, the one staircase region SR being disposed right in the plane of drawing, for example. In addition, in each of the second and third block regions BLK from the uppermost portion in the plane of drawing, one of the staircase regions SR on both sides in the X direction has the contacts CC coupled to the select gate line SGD, the one staircase region SR being disposed left in the plane of drawing, for example.

From the above, respective contacts CC of the staircase regions SR at both sides in the X direction illustrated in FIG. 1A are coupled to the memory cells belonging to different block regions BLK. In the staircase region SR on one side out of the staircase regions SR at both sides in the X direction, the plate-like portion LIy is disposed, and the contact CC coupled to the select gate line SGD is not disposed.

The word lines WL and the like stacked in multiple layers are individually drawn out by these contacts CC. More specifically, a write voltage, a read voltage, or the like are applied from these contacts CC to the memory cells included in the memory region MR at the central portion of the plurality of word lines WL via the word lines WL at the same height positions as the memory cells.

The plurality of word lines WL, the select gate lines SGD and SGS, the pillars PL, and the contacts CC are covered with an insulating layer 50. The insulating layer 50 also extends around these configurations.

The semiconductor substrate SB above the insulating layer 50 is, for example, a silicon substrate or the like. The peripheral circuit CBA including transistors TR, wirings, and the like is disposed on the surface of the semiconductor substrate SB. Various voltages applied from the contacts CC to the memory cells are controlled by the peripheral circuit CBA electrically coupled to the contacts CC. As a result, the peripheral circuit CBA controls the electrical operation of the memory cells.

The peripheral circuit CBA is covered with an insulating layer 40, and the insulating layer 40 and the insulating layer 50 covering the stacked body LM and the like are joined to each other, thereby forming the semiconductor memory device 1 including the configurations of the plurality of word lines WL, the select gate lines SGD and SGS, the pillars PL, the contacts CC, and the like, and the peripheral circuit CBA.

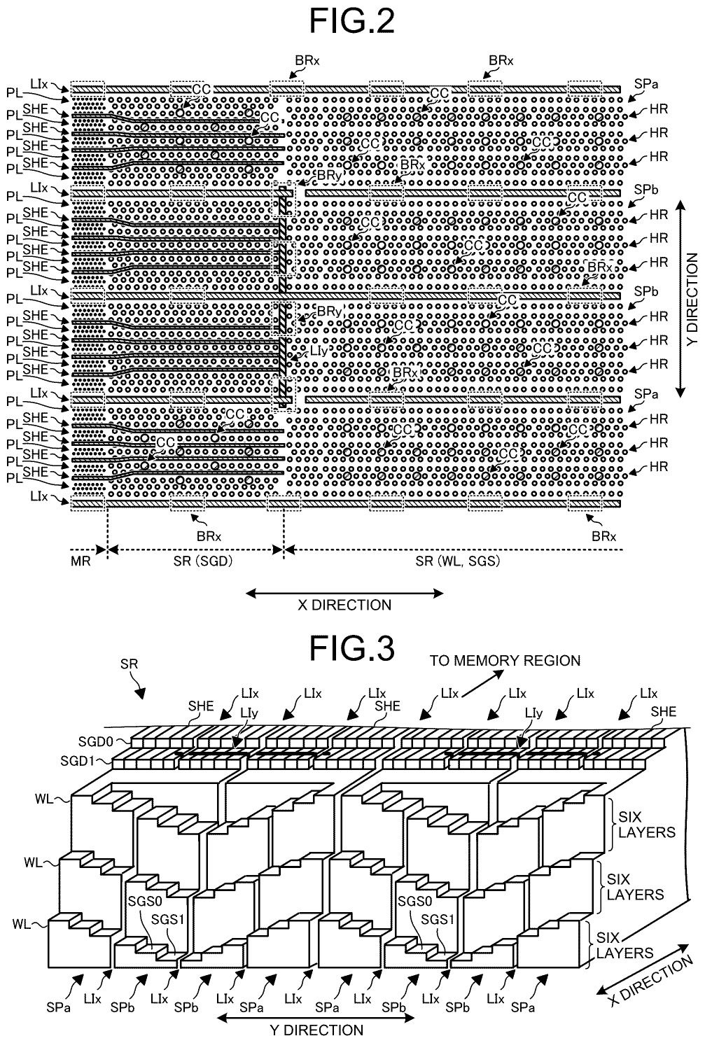

Next, a detailed layout of the semiconductor memory device 1 will be described with reference to FIG. 2.

FIG. 2 is an XY cross-sectional diagram illustrating an example of a detailed layout of the semiconductor memory device 1 according to the embodiment. More specifically, FIG. 2 is an XY cross-sectional diagram at the height position of the select gate line SGD, and includes a part of the staircase region SR on one side in the X direction of the stacked body LM and a part of the memory region MR.

As illustrated in FIG. 2, the staircase region SR on one side in the X direction of the stacked body LM has, for each region between the plate-like portions LIx adjacent in the Y direction, any one of staircase portions SPa and SPb including a portion in which the select gate line SGD is processed in a staircase shape, a portion in which the plurality of word lines WL are processed in a staircase shape, and a portion in which the select gate line SGS is processed in a staircase shape, in order from the side closer to the memory region MR.

More specifically, in the staircase region SR, a region separated by the separation layer SHE extending from the memory region MR corresponds to the portion in which the select gate line SGD is processed in a staircase shape. A region ahead of the end portion of the separation layer SHE in the X direction is a portion in which the plurality of word lines WL and the select gate line SGS are processed in a staircase shape.

As described above, the plurality of contacts CC respectively coupled to the plurality of word lines WL and the plurality of select gate lines SGD and SGS are disposed in the staircase region SR.

In the staircase portion SPa out of the staircase portions SPa and SPb, the plurality of contacts CC are disposed over the entire portion where the plurality of word lines WL and the select gate lines SGD and SGS are processed in a staircase shape, and are coupled to the word lines WL and the select gate lines SGD and SGS, respectively.

In addition, in the staircase portion SPb, the contact CC is not disposed in the portion where the select gate line SGD is processed in a staircase shape. The plurality of contacts CC are disposed in the portion where the plurality of word lines WL and the select gate lines SGS are processed in a staircase shape, and are coupled to the word lines WL and the select gate lines SGS, respectively.

Looking at the staircase portion SPa in FIG. 2, two contacts CC are disposed in each section of the individual select gate lines SGD separated by the separation layers SHE. That is, in the example of FIG. 2, the stacked body LM has two layers of the select gate lines SGD.

In addition, in each of the staircase portions SPa and SPb, the contacts CC arranged in the direction along the X direction are disposed in three rows for each of the individual regions divided by the plate-like portion LIx in a portion where the word lines WL and the select gate lines SGS are processed in a staircase shape.

This is because, in the example of FIG. 2, as the distance from the memory region MR increases, the word lines WL and the select gate lines SGS configuring the terrace surfaces of the staircase portions SPa and SPb are transferred to the lower layer side as described above, and the staircase portions SPa and SPb are configured such that the layers are transferred also in the Y direction.

In this manner, a staircase structure in which the layers such as the word lines WL configuring the terrace surfaces change not only in the X direction but also in the Y direction is also referred to as a multi-row staircase or the like. That is, the staircase structure in which the layers change in three stages in the Y direction is a three-row staircase. In the multi-row staircase, one step of the staircase may include a plurality of layers of word lines WL and the like in at least one direction of the X direction and the Y direction.

That is, the staircase portions SPa and SPb may be configured by displacing the layers of the word lines WL or the select gate lines SGS that configure the terrace surfaces arranged at the same position in the X direction, from each other in the Y direction. FIG. 2 illustrates an example of a three-row staircase in which terrace surfaces of three layers continuous in the stacking direction of the word lines WL or the select gate lines SGS are arranged in the Y direction at the same position in the X direction. In the example illustrated in FIG. 2 having such a configuration, three contacts CC are also disposed side by side in the Y direction at the same position in the X direction in order to be coupled to the word line WL and the select gate line SGS of each layer.

Details of a multi-row staircase structure illustrated in FIG. 2 will be described later.

Regardless of whether or not it is a multi-row staircase, the staircase portions SPa and SPb may include a staircase portion in which each step descends toward the memory region MR so as to face a staircase portion in which each step descends as the distance from the memory region MR increases. The contact CC is coupled to the staircase portion descending in the direction away from the memory region MR as described above, whereas the word line WL and the like of the staircase portion descending toward the memory region MR are in a floating state, for example, and the contact CC is not coupled.

The staircase portion SPa and the staircase portion SPb configured as described above are alternately disposed every two of the block regions BLK divided by the plate-like portion LIx.

Among them, the staircase portions SPb adjacent in the Y direction are divided by the plate-like portion LIx continuously extending in the direction along the X direction, and are electrically separated from each other. The staircase portion SPa and the staircase portion SPb adjacent in the Y direction are electrically coupled to each other via a gap of the plate-like portion LIx disposed between the staircase portion SPa and the staircase portion SPb, and each of the staircase portion SPa and the staircase portion SPb includes a portion where layers different from the other staircase portion SPa or SPb are processed in a staircase shape, the layers possibly including the word line WL and the select gate line SGS.

As an example, the staircase portion SPa may include a portion where lower side layers are processed in a staircase shape, and the staircase portion SPb may include a portion where upper side layers are processed in a staircase shape, the lower side layers including the word line WL and the select gate line SGS, the upper side layers including the word line WL. At this time, the number of layers of the staircase-shaped word line WL and the select gate line SGS included in the staircase portion SPa may be substantially equal to the number of layers of the staircase-shaped word line WL included in the staircase portion SPb.

As a result, one or more layers of the select gate line SGD included in the stacked body LM each has a terrace surface in both the staircase portions SPa and SPb adjacent in the Y direction, and the plurality of word lines WL and one or more layers of the select gate line SGS included in the stacked body LM each has a terrace surface in any one of the staircase portions SPa and SPb adjacent in the Y direction.

That is, the plurality of word lines WL and the plurality of select gate lines SGD and SGS included in the stacked body LM are drawn out throughout the staircase portions SPa and SPb adjacent in the Y direction. In view of this point, it can also be said that the semiconductor memory device 1 of the embodiment has a six-row staircase structure in which the three-row staircase of the staircase portion SPa and the three-row staircase of the staircase portion SPb adjacent thereto are combined.

In a portion where the select gate line SGD of the staircase portion SPb is processed in a staircase shape out of the staircase portions SPa and SPb, the plate-like portion LIy penetrating the stacked body LM and extending in the direction along the Y direction is disposed. The plate-like portion LIy extends across two block regions BLK adjacent in the Y direction including the staircase portion SPb. At this time, the plate-like portion LIy is divided by the plate-like portion LIx disposed between the two block regions BLK.

Both end portions of the plate-like portion LIy in the Y direction reach the plate-like portion LIx adjacent to the plate-like portion LIx dividing the plate- like portion LIy between the two block regions BLK on both sides in the Y direction. In the example of FIG. 2, at this time, the both end portions of the plate-like portion LIy are divided by these plate-like portions LIx. As described above, by crossing the end portions of the plate- like portions LIx and LIy in a cross shape, slight misalignment is allowed when these plate-like portions LIx and LIy are formed. However, an end portion of one of the plate-like portions LIx and LIy may be coupled to a side surface of the other, or the plate-like portions LIx and LIy may be coupled to each other at the end portions.

By disposing the plate-like portions LIx and LIy as described above, the individual memory regions MR belonging to the different block regions BLK are electrically separated from each other. In addition, these memory regions MR are coupled to the staircase portions SPa and SPb on one side for each block region BLK.

That is, in the example of FIG. 2, the memory regions MR respectively belonging to the block regions BLK at the uppermost portion and the lowermost portion in the plane of drawing are electrically coupled to the staircase portions SPa and SPb illustrated in FIG. 2. As a result, the transistors such as the memory cells included in these memory regions MR are electrically operated via the contacts CC, some of the contacts being disposed in the staircase portion SPa and being coupled to each of the select gate line SGD, some of the contacts CC being disposed in the staircase portions SPa and SPb and each being coupled to different layers that may include the word line WL or the select gate line SGS.

On the other hand, the memory regions MR respectively belonging to the two block regions BLK at the central portion in the plane of drawing are electrically separated from the staircase portion SPb illustrated in FIG. 2 by the plate-like portions LIy disposed in these block regions BLK. Note that these memory regions MR are electrically coupled to the staircase portions SPa and SPb (not illustrated) on the other side in the X direction of the stacked body LM. As a result, the transistors such as the memory cells included in these memory regions MR are electrically operated via the contacts CC disposed in the staircase portions SPa and SPb on the other side in the X direction.

The plate-like portion LIy only suffices to be able to electrically separate a portion where the plurality of word lines WL and the select gate line SGS of the staircase portion SPb are processed in a staircase shape from the memory region MR. Therefore, the plate-like portion LIy can be disposed at an arbitrary position in the X direction within the range of the portion where the select gate line SGD of the staircase portion SPb is processed in a staircase shape.

However, in order to suppress the influence of the plate-like portion LIy on the memory region MR, the plate-like portion LIy is preferably disposed at a position as far as possible from the memory region MR, such as in the vicinity of the boundary between the portion where the select gate line SGD is processed in a staircase shape and the portion where the plurality of word lines WL are processed in a staircase shape.

A plurality of bridge portions BRx and BRy are disposed at the upper end portions of the plate-like portions LIx and LIy.

The bridge portions BRx at the upper end portion of the plate-like portion LIx are disposed at intervals in the X direction. As will be described later, the bridge portion BRx is used as a countermeasure against stress when the stacked body LM is formed from a stacked body in which a sacrificial layer and an insulating layer are stacked. As described later, at the time of forming the stacked body LM from the stacked body including the sacrificial layer, a slit that becomes the plate-like portion LIx later is provided to penetrate the stacked body. At this time, stress may be generated on both sides in the Y direction of the slit. By providing the bridge portion BRx at the upper end portion of the slit, deformation of the slit due to the stress on both sides in the Y direction can be suppressed.

The bridge portions BRy at the upper end portion of the plate-like portion LIy are disposed at intervals in the Y direction. In a case where the plate-like portion LIy is disposed in the vicinity of the boundary between the portion where the select gate line SGD is processed in a staircase shape and the portion where the plurality of word lines WL are processed in a staircase shape, the bridge portion BRy can function as a stopper layer, for example, at the time of forming the separation layer SHE.

A plurality of pillars PL in which a plurality of memory cells are formed are disposed in the memory region MR, and a plurality of columnar portions HR are disposed in the staircase region SR. As described later, when forming the stacked body LM from a stacked body in which a sacrificial layer and an insulating layer are stacked, the columnar portions HR have a role of supporting these configurations and do not contribute to the function of the semiconductor memory device 1.

In the example of FIG. 2, the plurality of pillars PL and the columnar portions HR are all take a staggered arrangement. However, the plurality of pillars PL and the plurality of columnar portions HR may take an arrangement other than a staggered arrangement, for example, by disposing the plurality of columnar portions HR in a grid shape.

At the same height position of the stacked body LM, a cross-sectional area of the columnar portions HR in the direction along the XY plane is larger than, for example, a cross-sectional area of the pillars PL in the direction along the XY plane. In addition, a pitch between the plurality of columnar portions HR is larger than, for example, a pitch between the plurality of pillars PL, and an arrangement density of the columnar portions HR per unit area of the word line WL in the stacked body LM is lower than an arrangement density of the pillars PL per unit area of the word line WL.

As described above, for example, by configuring the cross-sectional area of the pillars PL to be smaller and having a narrower pitch than those of the columnar portions HR, a large number of memory cells can be formed at a high density in the stacked body LM having a predetermined size, and storage capacity of the semiconductor memory device 1 can be increased. On the other hand, since the columnar portions HR are exclusively used to support the stacked body LM, for example, by setting the cross-sectional area and the pitch to be larger than those of the pillar PL, processing accuracy at the time of forming the columnar portions HR can be relaxed.

Here, the above-described multi-row staircase structure will be described in more detail with reference to FIG. 3.

FIG. 3 is a schematic perspective diagram illustrating an example of the staircase region SR included on one side in the X direction in the stacked body LM of the semiconductor memory device 1 according to the embodiment. More specifically, FIG. 3 illustrates the staircase region SR corresponding to eight block regions BLK. In addition, as an example, the stacked body LM illustrated in FIG. 3 includes 16 layers of word lines WL, and two select gate lines SGD0 and SGD1 and two select gate lines SGS0 and SGS1 above and below these word lines WL in this order from the upper layer side in the stacking direction.

In FIG. 3, a shape of the word line WL and the like in the staircase region SR is mainly illustrated, and a part of the configuration of the contact CC and the like is omitted. In addition, the word lines WL and the like are stacked apart from each other by an insulating layer (not illustrated).

As illustrated in FIG. 3, each of the individual staircase portions SPa and SPb has, for example, a three-row staircase structure. Furthermore, in the staircase portion SPb out of the staircase portions SPa and SPb adjacent to each other in the Y direction, the terrace portions of the select gate lines SGS0 and SGS1 that are the lowermost layers of the stacked body LM are disposed on the opposite side of the staircase portion SPa in the Y direction. Furthermore, in the staircase portion SPa, the terrace portion of the uppermost word line WL belonging to the row in the Y direction is disposed on the opposite side of the staircase portion SPb in the Y direction.

That is, in the staircase portions SPa and SPb adjacent to each other in the Y direction, the terrace portion of the word line WL or the select gate line SGS ascends one layer at a time from the staircase portion SPb side to the staircase portion SPa side in the Y direction. As a result, in the terrace portions adjacent to each other in the Y direction, a total number of layers of the word line WL and the select gate line SGS included in the stacking direction of one terrace portion is, for example, 2n layers, and a total number of layers of the word line WL and the select gate line SGS included in the stacking direction of a terrace portion adjacent thereto is, for example, (2n+1) layers.

In the staircase portions SPa and SPb, the layers of the select gate lines SGD0 and SGD1 having the terrace portions in the region closest to the memory region MR do not change in the Y direction.

On the other hand, in a pair of the staircase portions SPa and SPb adjacent to each other in the Y direction, the terrace portions of the word lines WL and the like ascend by six layers at a time in the X direction toward the memory region MR. However, the terrace portions of the select gate lines SGD0 and SGD1 ascend one layer at a time in the X direction toward the memory region MR.

As described above, the word lines WL and the like configuring the terrace portions change one layer at a time in the Y direction and change six layers at a time in the X direction, whereby all the word lines WL and the select gate lines SGS included in the stacked body LM have the terrace portions in any one of the staircase portions SPa and SPb. As described above, the pair of staircase portions SPa and SPb adjacent in the Y direction are coupled to the memory region MR belonging to one block region BLK. Therefore, the plurality of word lines WL and the select gate lines SGD and SGS in the stacked body LM can be drawn by the pair of staircase portions SPa and SPb.

In addition, similarly to the pair of staircase portions SPa and SPb described above, a pair of staircase portions SPa and SPb adjacent to this pair in the Y direction also have a terrace portions of the word lines WL or the select gate lines SGS that ascend one layer at a time from the staircase portion SPb side to the staircase portion SPa side in the Y direction and ascend six layers at a time in the X direction toward the memory region MR. At this time, these staircase portions SPa and SPb are disposed such that arrangement of terrace portions of a plurality of pairs of the staircase portions SPa and SPb is line-symmetric in the Y direction.

As a result, the staircase portions SPa adjacent to each other in the Y direction have a mountain shape in which a boundary portion of the staircase portions SPa is high when a YZ cross section is viewed from the X direction. In addition, the staircase portions SPb adjacent to each other in the Y direction have a valley shape in which a boundary portion of the staircase portions SPb is lowered when the YZ cross section is viewed from the X direction.

Note that the staircase region SR of the stacked body LM on the other side in the X direction with respect to the plurality of staircase portions SPa and SPb illustrated in FIG. 3 can be configured similarly to the staircase portions SPa and SPb illustrated in FIG. 3. At this time, the shape of the staircase regions SR on both sides in the X direction of the stacked body LM may be configured to be line-symmetric in the X direction, or the arrangement of the terrace portion of each layer may be reversed in the Y direction at both end portions in the X direction.

That is, in a case where the shape of the pair of staircase portions SPa and SPb adjacent in the Y direction is configured to be line-symmetric in the X direction on both sides in the X direction of the stacked body LM, the direction in which steps ascend one layer at a time in the Y direction in the staircase portions SPa and SPb is reversed in the staircase regions SR at both end portions in the X direction of the stacked body LM. This is because the positions where the plate-like portions LIy are disposed on both sides in the X direction are different for every two of the block regions BLK.

Therefore, in a case where the shapes of the pair of staircase portions SPa and SPb adjacent in the Y direction are inverted in the Y direction on both sides in the X direction of the stacked body LM, the direction in which steps ascend one layer at a time in the Y direction in the staircase portions SPa and SPb coincides with the staircase regions SR at the both end portions in the X direction of the stacked body LM.

As described above, in FIG. 3, the case where the staircase portion SPa or the staircase portion SPb belonging to one block region BLK each has the three-row staircase structure has been described. However, as described above, the number of staircase rows in each of the staircase portions SPa and SPb in the Y direction is not limited to three, and may be one row, two rows, or four or more rows.

In addition, it is also possible to change the arrangement order of the plurality of staircase portions SPa and SPb in the Y direction illustrated in FIG. 3. For example, in FIG. 3, the staircase portions SPa and SPb are disposed in an order of the staircase portions SPa, SPb, SPb, SPa, SPa, SPb, SPb, and SPa from one side in the Y direction. On the other hand, for example, the staircase portions SPa and SPb may be disposed in an order of the staircase portions SPb, SPa, SPa, SPb, SPb, SPa, SPa, and SPb.

Even in such an arrangement order, each pair of the staircase portions SPa and SPb adjacent in the Y direction can be disposed such that the arrangement of the terrace portions in these pairs is line-symmetric in the Y direction.

Furthermore, in the example of FIG. 3, each pair of the staircase portions SPa and SPb adjacent in the Y direction is disposed such that the arrangement of the terrace portions in these pairs is line-symmetric in the Y direction. However, the arrangement of these pairs may not be line-symmetric in the Y direction.

As an example, in one pair of the staircase portions SPa and SPb, these pairs can be configured such that the terrace portions such as the word lines WL ascend one layer at a time from one side to the other side in the Y direction, and in the next pair adjacent in the Y direction to the terrace portion of the uppermost word line WL belonging to the same row in the Y direction of the above pair, the next pair can be configured such that the terrace portions of the word lines WL and the like ascend one layer at a time in the same direction in the Y direction as the first pair.

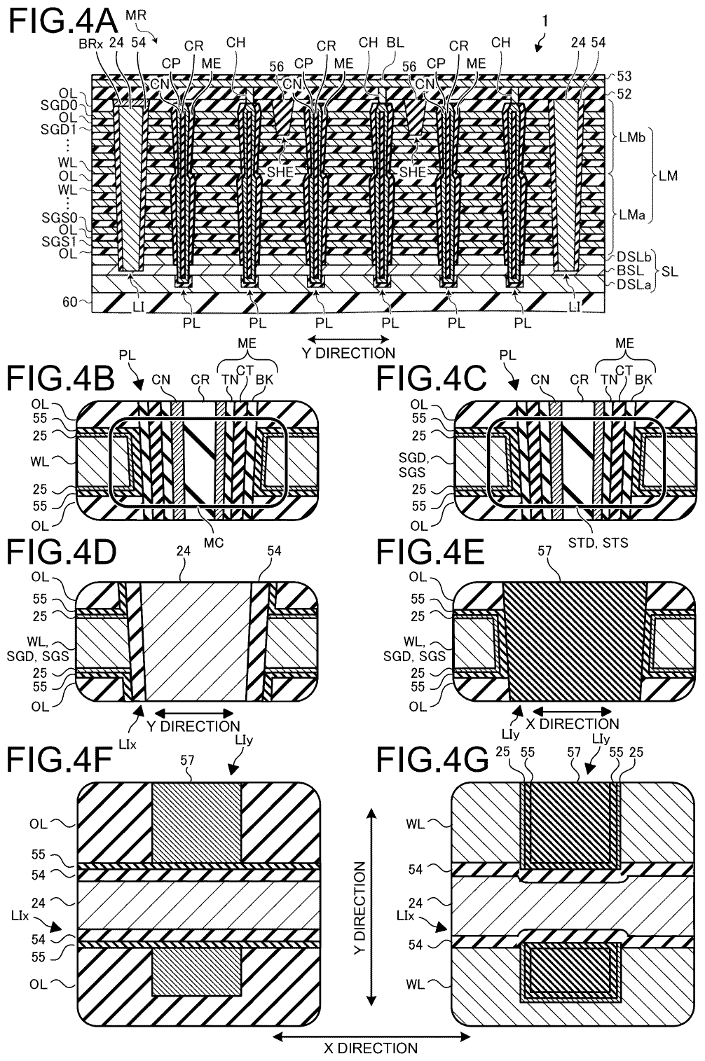

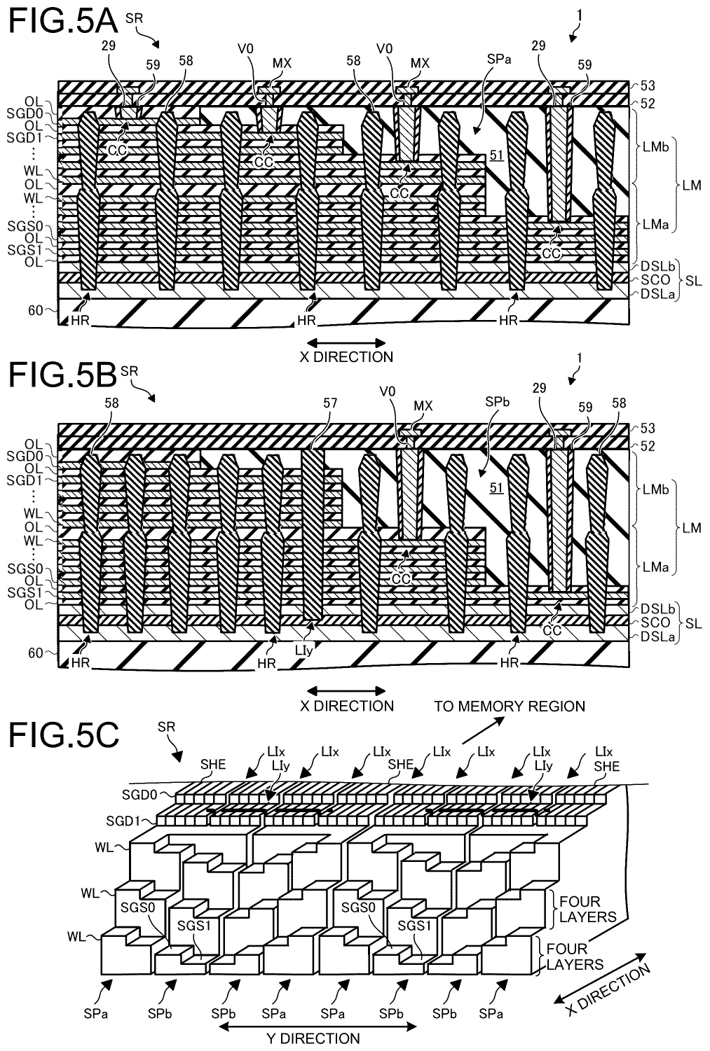

Next, a detailed configuration example of the semiconductor memory device 1 will be described with reference to FIGS. 4A to 5C. FIGS. 4A to 5C are cross-sectional diagrams illustrating an example of a configuration of the semiconductor memory device 1 according to the embodiment.

More specifically, FIG. 4A is a cross-sectional diagram along the Y direction in the memory region MR of the semiconductor memory device 1. In FIG. 4A, structures below the insulating layer 60 and above an insulating layer 53 described later are omitted.

FIG. 4B is an enlarged cross-sectional diagram of the pillar PL at the height position of the word line WL. FIG. 4C is an enlarged cross-sectional diagram of the pillar PL at the height position of the select gate lines SGD and SGS.

FIG. 4D is an enlarged cross-sectional diagram along the Y direction of the plate-like portion LIx at the height position of the word line WL and the select gate lines SGD and SGS. FIG. 4E is an enlarged cross-sectional diagram along the X direction of the plate-like portion LIy at the height position of the word line WL and the select gate lines SGD and SGS.

FIG. 4F is an XY cross-sectional diagram illustrating an intersection of the plate-like portions LIx and LIy at a height position of an arbitrary insulating layer OL. FIG. 4G is an XY cross-sectional diagram illustrating an intersection of the plate-like portions LIx and LIy at a height position of an arbitrary word line WL.

FIG. 5A is a cross-sectional diagram along the X direction of the staircase portion SPa included in the staircase region SR of the semiconductor memory device 1. FIG. 5B is a cross-sectional diagram along the X direction of the staircase portion SPb included in the staircase region SR of the semiconductor memory device 1. In FIGS. 5A and 5B, structures below the insulating layer 60 and above the insulating layer 53 described later are omitted.

FIG. 5C is a schematic perspective diagram illustrating another example of the staircase region SR included on one side in the X direction in the stacked body LM of the semiconductor memory device 1 according to the embodiment.

Note that in the present specification, the direction in which the terrace surface of the word line WL of each step in the staircase region SR faces is defined as an upward direction in the semiconductor memory device 1.

As illustrated in FIG. 4A, the source line SL has a multilayer structure in which, for example, a lower source line DSLa, an intermediate source line BSL, and an upper source line DSLb are stacked in this order on the insulating layer 60. The intermediate source line BSL is disposed below the stacked body LM in the memory region MR.

The lower source line DSLa, the intermediate source line BSL, and the upper source line DSLb are, for example, polysilicon layers. Among them, at least the intermediate source line BSL may be a conductive polysilicon layer or the like in which impurities are diffused.

The source line SL is coupled to the peripheral circuit CBA via the electrode film EL by a through contact (not illustrated) extending from the electrode film EL to the peripheral circuit CBA in the insulating layer 50 outside the stacked body LM.

The stacked body LM is disposed above the source line SL. The stacked body LM includes stacked bodies LMa and LMb in which a plurality of word lines WL and a plurality of insulating layers OL are alternately stacked one layer at a time.

The stacked body LMa is disposed above the source line SL. The plurality of select gate lines SGS0 and SGS1 are disposed in this order from the upper layer side of the stacked body LMa via the insulating layer OL below the lower layer of the lowermost word line WL of the stacked body LMa. The stacked body LMb is disposed above the stacked body LMa. The plurality of select gate lines SGD0 and SGD1 are disposed in this order from the upper layer side of the stacked body LMb via the insulating layer OL above the upper layer of the uppermost word line WL of the stacked body LMb.

However, the number of the word lines WL and the select gate lines SGD and SGS stacked in the stacked body LM is arbitrary. The word line WL and the select gate lines SGD and SGS are, for example, a tungsten layer or a molybdenum layer. The insulating layer OL is, for example, a silicon oxide layer or the like.

The upper surface of the stacked body LM is covered with an insulating layer 52. The insulating layer 52 is covered with the insulating layer 53. The insulating layers 52 and 53 respectively configure a part of the insulating layer 50 in FIG. 1A together with an insulating layer 51 described later.

As described above, the stacked body LM is divided in the Y direction by the plurality of plate-like portions LIx. That is, the respective plate-like portions LIx are arranged side by side in the Y direction and extend in the stacking direction of the stacked body LM and the direction along the X direction.

As described above, the plate-like portion LIx extends substantially continuously in the stacked body LM from one end portion to the other end portion of the stacked body LM in the X direction except for the above-described gap portion. The plate-like portion LIx penetrates the stacked body LM and the upper source line DSLb and reaches the intermediate source line BSL in the memory region MR.

In addition, the plate-like portion LIx has, for example, a tapered shape in which the width in the Y direction decreases from the upper end portion toward the lower end portion. Alternatively, the plate-like portion LIx has, for example, a bowing shape in which the width in the Y direction is maximized at a predetermined position between the upper end portion and the lower end portion.

Each of the plate-like portions LIx includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers side walls of the plate-like portion LIx facing each other in the Y direction. The conductive layer 24 is filled inside the insulating layer 54, and electrically coupled to the source line SL including the intermediate source line BSL.

However, instead of the plate-like portion LIx, a plate-like member filled with an insulating layer may penetrate the stacked body LM and extend in the direction along the X direction, thereby dividing the stacked body LM in the Y direction.

A plurality of bridge portions BRx are disposed at predetermined intervals in the X direction at the upper end portion of the plate-like portion LIx. As described later, the bridge portion BRx is formed so as to be embedded in the upper end portion of the plate-like portion LIx located on the upper surface of the uppermost insulating layer OL of the stacked body LM. Therefore, in the portion where the bridge portion BRx is disposed, a part of the upper end portion of the plate-like portion LIx is replaced with the constituent material of the bridge portion BRx.

The bridge portion BRx is, for example, a polysilicon layer or a silicon oxide layer. By disposing the plurality of bridge portions BRx at predetermined intervals at the upper end portion of the plate-like portion LIx, as described above, deformation of the slit that becomes the plate-like portion LIx later due to the stress generated on both sides in the Y direction of the slit is suppressed. For example, when the width of the slit in the Y direction changes due to the stress deformation, there is a possibility that positional displacement in the Y direction occurs between the pillar PL already formed in the memory region MR at this time point and a plug CH to be coupled above the pillar PL thereafter. Since the bridge portion BRx suppresses deformation of the slit width, it is possible to suppress a coupling failure due to the positional displacement between the pillar PL and the plug CH, an operation failure of the memory cells MC due to these coupling failures, or the like.

In FIG. 4A, in order to illustrate the shapes of both the plate-like portions LIx in the portion having the bridge portion BRx and the portion not having the bridge portion BRx, the bridge portion BRx is illustrated only on one side of the plate-like portions LIx respectively disposed on both sides in a left-right direction in the plane of drawing. As described above, the bridge portions BRx may be disposed at different positions in the X direction in the plate-like portions LIx adjacent to each other in the Y direction, or may be disposed such that the positions in the X direction coincide with each other in the plurality of plate-like portions LIx as illustrated in FIG. 2.

Between the plate-like portions LIx adjacent in the Y direction, the plurality of separation layers SHE penetrating an upper layer portion of the stacked body LMb and extending in the direction along the X direction are disposed. These separation layers SHE are insulating layers 56 such as a silicon oxide layer that penetrate the select gate lines SGD0 and SGD1 and reach the insulating layer OL immediately below the select gate line SGD1.

In other words, between the plate-like portions LIx in the X direction, these separation layers SHE penetrating the upper layer portion of the stacked body LMb extend in the memory region MR and a part of the staircase region SR, so that the upper layer portion of the stacked body LMb is partitioned into the select gate lines SGD0 and SGD1 described above.

In the memory region MR, a plurality of pillars PL penetrating the stacked body LM, the upper source line DSLb, and the intermediate source line BSL and reaching the lower source line DSLa are dispersedly disposed.

As described above, the plurality of pillars PL take, for example, a staggered arrangement when viewed from the stacking direction of the stacked body LM. Each of individual pillars PL has, for example, a circular shape, an elliptical shape, an oval shape, or the like as a cross-sectional shape in a direction along the layer direction of the stacked body LM, that is, in a direction along the XY plane.

In addition, each of the pillars PL has a tapered shape in which the diameter and the cross-sectional area decrease from the upper layer side toward the lower layer side in a portion penetrating the stacked body LMa and a portion penetrating the stacked body LMb. Alternatively, each of the pillars PL has a bowing shape in which the diameter and the cross-sectional area are maximized at a predetermined position between the upper layer side and the lower layer side, for example, in a portion penetrating the stacked body LMa and a portion penetrating the stacked body LMb.

Each of the plurality of pillars PL has a memory layer ME extending in the stacked body LM in the stacking direction, a channel layer CN penetrating the stacked body LM and coupled to the intermediate source line BSL, a cap layer CP covering an upper surface of the channel layer CN, and a core layer CR serving as a core material of the pillar PL.

As illustrated in FIGS. 4B and 4C, the memory layer ME has a multilayer structure in which a block insulating layer BK, a charge storage layer CT, and a tunnel insulating layer TN are stacked in this order from an outer peripheral side of the pillar PL. More specifically, the memory layer ME is disposed on side surfaces of the pillar PL except for a depth position of the intermediate source line BSL. In addition, the memory layer ME is also disposed on a bottom surface of the pillar PL reaching the depth of the lower source line DSLa.

Inside the memory layer ME, the channel layer CN penetrates the stacked body LM, the upper source line DSLb, and the intermediate source line BSL, and reaches the depth of the lower source line DSLa. More specifically, the channel layer CN is disposed on the side surfaces and the bottom surface of the pillar PL being covered with the memory layer ME. However, a part of the channel layer CN is in contact with the intermediate source line BSL on the side surfaces, and is electrically coupled to the source line SL including the intermediate source line BSL. The core layer CR is filled further inside the channel layer CN.

Each of the plurality of pillars PL has a cap layer CP at the upper end portion. The cap layer CP is disposed at the upper end portion of the pillar PL so as to cover at least the upper end portion of the channel layer CN, and is coupled to the channel layer CN. In addition, the cap layer CP is coupled to a bit line BL disposed in the insulating layer 53 via the plug CH disposed in the insulating layer 52. The bit line BL extends above the stacked body LM in the direction along the Y direction so as to intersect the drawing direction of the word line WL.

In FIG. 4A, out of the six pillars PL, the plugs CH are coupled only to three pillars PL which respectively penetrate the select gate line SGD separated into three and are electrically coupled to the bit line BL illustrated in FIG. 4A. The other pillars PL are coupled to another bit line BL extending in the direction along the Y direction in parallel with the bit line BL illustrated in FIG. 4A via a plug CH (not illustrated in FIG. 4A) at positions different from the cross section illustrated in FIG. 4A.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN and the cap layer CP are semiconductor layers such as a polysilicon layer or an amorphous silicon layer.

As illustrated in FIG. 4B, with the above configuration, the memory cells MC are respectively formed in portions facing the individual word lines WL on the side surfaces of the pillars PL, respectively. When a predetermined voltage is applied from the word line WL, data is written to and read from the memory cells MC.

In addition, as illustrated in FIG. 4C, select gates STD are respectively formed in portions where the side surfaces of the pillars PL face the select gate lines SGD0 and SGD1 above the word lines WL, respectively. In addition, select gates STS are respectively formed in portions where the side surfaces of the pillars PL face the select gate lines SGS0 and SGS1 below the word lines WL, respectively.

When predetermined voltages are applied from the select gate lines SGD and SGS respectively, the select gates STD and STS are turned on or off, and the memory cells MC of the pillar PL to which the select gates STD and STS belong can be brought into a selected state or a non-selected state.

As illustrated in FIGS. 4B and 4C, a conductive metal element-containing layer 25 and an insulating metal element-containing layer 55 are disposed in this order on both surfaces of each of the word line WL and the select gate lines SGD and SGS in the stacking direction of the stacked body LM.

When the word line WL and the like is a tungsten layer or the like, the metal element-containing layer 25 is, for example, at least one of a titanium layer, a titanium nitride layer, a tantalum layer, or a tantalum nitride layer, and functions as a barrier metal layer that suppresses diffusion of tungsten atoms into the configuration in the vicinity of the word line WL. When the word line WL and the like is a molybdenum layer or the like, the metal element-containing layer 25 is, for example, a molybdenum nitride layer or the like, and functions as a precursor when the word line WL and the like is formed.

The metal element-containing layer 55 is, for example, an aluminum oxide (Al₂O₃) layer or the like, and functions as a block insulating layer in the memory cell MC.

As described above, these metal element-containing layers 25 and 55 are disposed on both surfaces of the word line WL and the like in the stacking direction, and are also disposed in this order on the end surface of the word line WL and the like facing the side wall of the pillar PL.

As illustrated in FIGS. 5A and 5B, the staircase region SR has staircase portions SPa and SPb in which a plurality of word lines WL and select gate lines SGD and SGS are processed in a staircase shape. For convenience of description, FIGS. 5A and 5B illustrate an example of a two-row staircase having two rows of staircases per one block region BLK, unlike the example of the three-row staircase illustrated in FIG. 2 and the like described above.

As illustrated in FIG. 5C, even in a case where the staircase region SR has a two-row staircase structure, the arrangement method of the terrace portion of each layer in the staircase portions SPa and SPb is similar to the case of the three-row staircase in FIG. 3 described above. That is, in the staircase portions SPa and SPb adjacent to each other in the Y direction, the terrace portions of the word lines WL or the select gate lines SGS ascend one layer at a time from the staircase portion SPb side to the staircase portion SPa side in the Y direction. On the other hand, the word lines WL and the select gate lines SGS configuring the terrace portions change by four layers at a time in the X direction.

The staircase portion SPa illustrated in FIG. 5A is a cross section of a row including the terrace portions of the word lines WL on the lower layer side belonging to the same row in the Y direction in the two-row staircase of the staircase portion SPa illustrated in FIG. 5C. The staircase portion SPb illustrated in FIG. 5B is also a cross section of a row including the terrace portions of the word lines WL on the lower layer side belonging to the same row in the Y direction in the two-row staircase of the staircase portion SPb illustrated in FIG. 5C.

The staircase portions SPa and SPb are covered with the insulating layer 51. The insulating layer 51 reaches, for example, the height position of the uppermost layer of the stacked body LM, and the insulating layers 52 and 53 also cover the upper surface of the insulating layer 51. As described above, the insulating layer 51 also configures a portion of the insulating layer 50 of FIG. 1A.

In the staircase region SR, instead of the intermediate source line BSL, the source line SL includes an intermediate insulating layer SCO interposed between the upper source line DSLb and the lower source line DSLa. The intermediate insulating layer SCO is, for example, a silicon oxide layer or the like.

Therefore, the plate-like portion LIx (not illustrated in FIGS. 5A to 5C) penetrates the insulating layer 51, the stacked body LM, and the upper source line DSLb and reaches the intermediate insulating layer SCO in the staircase region SR.

As illustrated in FIG. 5A, the staircase portion SPa includes a plurality of contacts CC respectively coupled to some of the plurality of word lines WL and the select gate lines SGD. Each of the individual contacts CC penetrates the insulating layer 51 and the like and is coupled to the word lines WL or the select gate lines SGD immediately below the insulating layers OL configuring each step of the staircase portion SPa.

As illustrated in FIG. 5B, the staircase portion SPb includes the plate-like portion LIy in a portion where the select gate lines SGD are processed in a staircase shape. The plate-like portion LIy is a single body of the insulating layer 57 such as a silicon oxide layer. In addition, the staircase portion SPb includes a plurality of contacts CC respectively coupled to some of the plurality of word lines WL and the select gate lines SGS.

That is, in the staircase portion SPb, the contacts CC are coupled to the word lines WL belonging to layers different from the word lines WL coupled to the contacts CC in the staircase portion SPa adjacent in the Y direction.

In the staircase portion SPb, each of the individual contacts CC penetrates the insulating layer 51 and the like and is coupled to the word lines WL or the select gate lines SGS immediately below the insulating layers OL configuring each step of the staircase portion SPb. As described above, the contact CC coupled to the select gate line SGD is not disposed in the staircase portion SPb.

In the staircase portions SPa and SPb, each of the contacts CC has, for example, a tapered shape in which a diameter and a cross-sectional area decrease from an upper end portion toward a lower end portion. Alternatively, the contact CC has, for example, a bowing shape in which the diameter and the cross-sectional area are maximized at a predetermined position between the upper end portion and the lower end portion.

In addition, the contact CC has an insulating layer 59 covering an outer periphery of the contact CC, and a conductive layer 29 such as a tungsten layer or a copper layer filled inside the insulating layer 59.

The insulating layer 59 is a liner layer of the contact CC. The conductive layer 29 corresponds to the core material of the contact CC and is coupled to an upper layer wiring MX disposed in the insulating layer 53 via a plug VO disposed in the insulating layer 52. The upper layer wiring MX is electrically coupled to the peripheral circuit CBA (see FIG. 1A).

With such a configuration, the respective layers of the word lines WL and the select gate lines SGD and SGS of the upper and lower layers of the word lines WL can be electrically drawn on both sides in the X direction of the stacked body LM. That is, with the above configuration, a predetermined voltage is applied from the peripheral circuit CBA to the memory cells MC via the upper layer wiring MX, the contact CC, the word line WL, and the like, and the memory cells MC can be operated as memory elements.

In addition, in the staircase region SR including the staircase portions SPa and SPb, a plurality of columnar portions HR penetrating the insulating layer 51, the stacked body LM, the upper source line DSLb, and the intermediate insulating layer SCO and reaching the lower source line DSLa are dispersedly disposed. Each of the plurality of columnar portions HR is a single body of an insulating layer 58 such as a silicon oxide layer extending in the stacked body LM in the stacking direction.

As described above, the plurality of columnar portions HR take, for example, a staggered or a grid arrangement when viewed from the stacking direction of the stacked body LM. Each of the individual columnar portions HR has, for example, a circular shape, an elliptical shape, an oval shape, or the like as a cross-sectional shape in a direction along the layer direction of the stacked body LM, that is, a direction along the XY plane.

In addition, each of the columnar portions HR has a tapered shape in which the diameter and the cross-sectional area decrease from the upper layer side toward the lower layer side in a portion penetrating the stacked body LMa and a portion penetrating the stacked body LMb. Alternatively, each of the columnar portions HR has a bowing shape in which the diameter and the cross-sectional area are maximized at a predetermined position between the upper layer side and the lower layer side, for example, in a portion penetrating the stacked body LMa and a portion penetrating the stacked body LMb.

FIGS. 4D to 4G illustrate the arrangement of the metal element-containing layers 25 and 55 in the periphery of the plate-like portions LIx and LIy.

As illustrated in FIGS. 4E to 4G, the metal element-containing layers 25 and 55 are disposed in the same manner as in the periphery of the pillar PL, in the periphery of the plate-like portion LIy. That is, the metal element-containing layers 25 and 55 are disposed on the surfaces of the word lines WL and the like on both sides in the stacking direction in this order, and are also disposed on the end surfaces of the word lines WL and the like facing the side surfaces of the plate-like portion LIy in the X direction in this order.

As illustrated in FIGS. 4D and 4G, in the periphery of the plate-like portion LIx, the metal element-containing layers 25 and 55 are not disposed on the side surface of the plate-like portion LIx in the Y direction at the height position of the word line WL and the like, and the end surface of the word line WL and the like facing the side surface of the plate-like portion LIx in the Y direction is in direct contact with the side surface of the plate-like portion LIx in the Y direction.

However, as illustrated in FIG. 4G, at the intersection with the plate-like portion LIy, the metal element-containing layer 55 is interposed between the plate-like portion LIx and the plate-like portion LIy at the height position of the word line WL and the like. Note that the metal element-containing layer 55 interposed between the plate-like portion LIx and the plate-like portion LIy may protrude to the inside of the plate-like portion LIx by the thickness of the metal element-containing layer 55, for example, whereby the insulating layer 54 of the side walls of the plate-like portion LIx may also slightly protrude to the inside of the plate-like portion LIx at the intersection with the plate-like portion LIy.

As illustrated in FIGS. 4D and 4F, in the periphery of the plate-like portion LIx, the end surface of the insulating layer OL faces the side surface of the plate-like portion LIx in the Y direction at the height position of the insulating layer OL via the metal element-containing layer 55. As described above, the metal element-containing layer 55 extends over both surfaces in the stacking direction of the word line WL and the like and further extends over the end surface facing the plate-like portion LIx of the insulating layer OL adjacent to the word line WL in the stacking direction, so that the metal element-containing layer 55 is interposed between the end surface of the insulating layer OL and the side surface of the plate-like portion LIx.

That is, as illustrated in FIG. 4F, the metal element-containing layer 55 continuously extends on the side surface of the plate-like portion LIx in the Y direction at the height position of the insulating layer OL in the X direction. Thus, at the intersection with the plate-like portion LIy, the metal element-containing layer 55 is interposed between the plate-like portion LIx and the plate-like portion LIy even at the height position of the insulating layer OL.

### Method for Manufacturing Semiconductor Memory Device

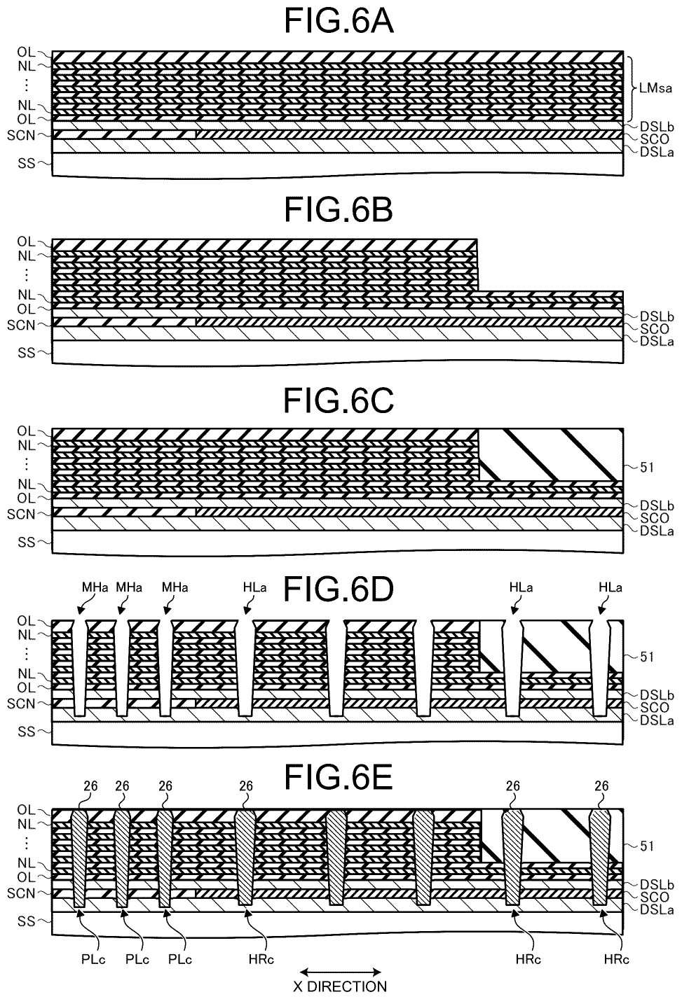

Next, a method for manufacturing the semiconductor memory device 1 of the embodiment will be described with reference to FIGS. 6A to 16 Db. FIGS. 6A to 12C among FIGS. 6A to 16 Db are diagrams sequentially exemplifying a part of a procedure of the method for manufacturing the semiconductor memory device 1 according to the embodiment.

First, FIGS. 6A to 6E illustrate a stacked body LMsa which is a lower layer portion of the stacked body LM before the word line WL is formed and a state in which various configurations are formed in the stacked body LMsa. FIGS. 6A to 6E are cross-sectional diagrams along the X direction of the regions that become the memory region MR and the staircase region SR later.

As illustrated in FIG. 6A, the lower source line DSLa, an intermediate sacrificial layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate, a conductive substrate, or the like can be used. The above-described insulating layer 60 (see FIGS. 4A to 5C and the like) may be formed on an upper surface side of the support substrate SS.

The intermediate sacrificial layer SCN is formed in a region on the support substrate SS that becomes the memory region MR later, and the intermediate insulating layer SCO is formed in a region on the support substrate SS that becomes the staircase region SR later. The intermediate sacrificial layer SCN is, for example, a silicon nitride layer or the like, and is a layer to be replaced with a polysilicon layer or the like and become the intermediate source line BSL later. As described above, the intermediate insulating layer SCO is, for example, a silicon oxide layer or the like.

In addition, the stacked body LMsa in which a plurality of insulating layers NL and a plurality of insulating layers OL are alternately stacked one layer at a time is formed above the upper source line DSLb. The insulating layer NL is, for example, a silicon nitride layer or the like, and functions as a sacrificial layer to be replaced with a conductive material and becomes the word line WL or the select gate line SGS later.

As illustrated in FIG. 6B, the insulating layers NL and the insulating layers OL are processed in a staircase shape in a partial region of the stacked body LMsa. Such processing can be performed by repeating slimming of a mask pattern such as a photoresist layer and etching of the insulating layers NL and the insulating layers OL of the stacked body LMsa a plurality of times.

That is, the mask pattern is formed on the upper surface of the stacked body LMsa, and for example, the insulating layer NL and the insulating layer OL in an exposed portion are paired and removed by etching a plurality of layers at a time. In addition, by processing with oxygen plasma or the like, an end portion of the mask pattern is retracted to newly expose the upper surface of the stacked body LMsa, and the insulating layer NL and the insulating layer OL are further removed by etching a plurality of layers at a time. By repeating such processing a plurality of times, the staircase shape is formed.

At this time, the number of layers of the insulating layers NL and the insulating layers OL removed by one-time etching corresponds to the number of rows of the staircases finally included in the staircase portions SPa and SPb. That is, for example, in a case of forming a pair of staircase portions SPa and SPb each having a two-row staircase structure, four pairs of the insulating layers NL and the insulating layers OL are removed by one-time etching.

As illustrated in FIG. 6C, the insulating layer 51 covering the staircase portion and reaching the height of the upper surface of the stacked body LMsa is formed. The insulating layer 51 is also formed in an outer region of the stacked body LMsa.

As illustrated in FIG. 6D, a plurality of memory holes MHa and holes HLa extending in the stacking direction of the stacked body LMsa are formed. The memory hole MHa is a portion that becomes a lower structure of the pillar PL later, and is disposed in a region that becomes the memory region MR later. The hole HLa is a portion that becomes a lower structure of the columnar portions HR later, and is disposed in a region that becomes the staircase region SR later.

The memory holes MHa and the holes HLa penetrate the stacked body LMsa, the upper source line DSLb, and the intermediate sacrificial layer SCN or the intermediate insulating layer SNO, and reach the lower source line DSLa.

As illustrated in FIG. 6E, the plurality of memory holes MHa and the holes HLa are filled with a sacrificial layer 26 such as an amorphous silicon layer or a CVD-carbon layer. As a result, pillars PLc in which the plurality of memory holes MHa are filled with the sacrificial layer 26 are formed in the region that becomes the memory region MR later. In addition, columnar portions HRc in which the plurality of holes HLa are filled with the sacrificial layer 26 are formed in the region that becomes the staircase region SR later.

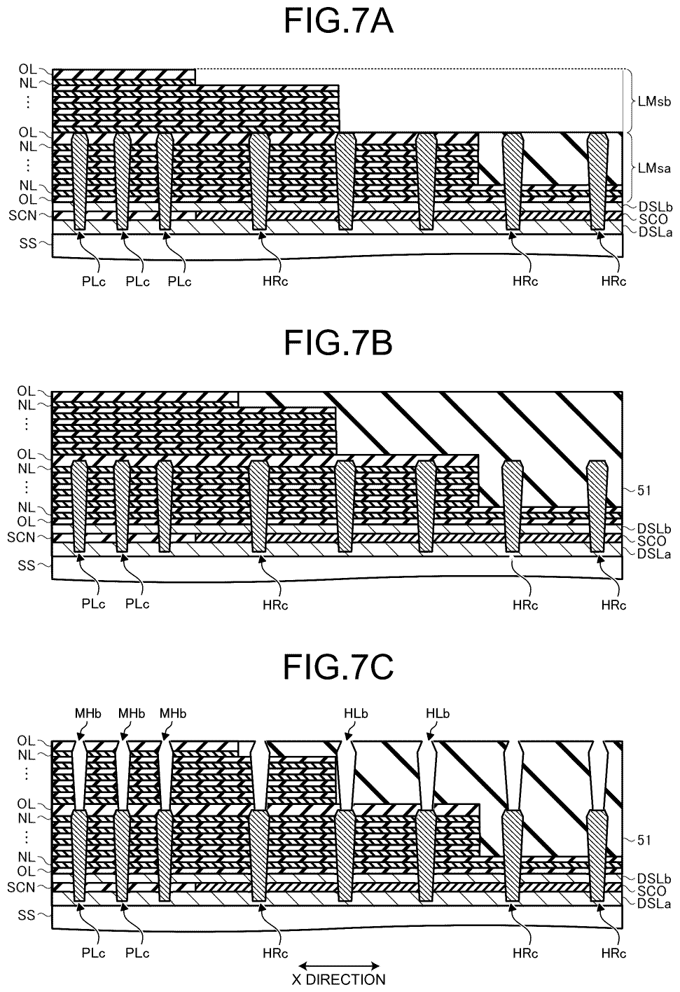

Next, FIGS. 7A to 7C illustrate a state in which a stacked body LMsb which is an upper layer portion of the stacked body LM before the word line WL is formed is formed, and various configurations are formed in the stacked bodies LMsa and LMsb. FIGS. 7A to 7C are cross-sectional diagrams of regions that become the memory region MR and the staircase region SR later along the X direction, similarly to FIGS. 6A to 6E described above.

As illustrated in FIG. 7A, the stacked body LMsb in which a plurality of insulating layers NL and a plurality of insulating layers OL are alternately stacked one layer at a time and which covers the stacked body LMsa including a portion processed in the staircase shape is formed, and an end portion in the X direction is processed in a staircase shape. The insulating layer NL of the stacked body LMsb is replaced with a conductive layer and becomes the word line WL or the select gate line SGD later.

More specifically, after the stacked body LMsb covering the entire stacked body LMsa is formed, the insulating layer NL and the insulating layer OL are processed in a staircase shape in a partial region of the stacked body LMsb. Such processing can be performed by repeating the slimming of the mask pattern such as the photoresist layer and the etching of the insulating layer NL and the insulating layer OL of the stacked body LMsb a plurality of times, similarly to the processing illustrated in FIG. 6B described above.

At this time, an uppermost step of the staircase portion formed in the stacked body LMsa and a lowermost step of the staircase portion formed in the stacked body LMsb are brought close to each other, and are formed so as to be continuously connected from the lower layer side of the stacked body LMsa to the upper layer side of the stacked body LMsb.

As illustrated in FIG. 7B, an insulating layer 51 covering the upper surface of the insulating layer 51 covering the staircase portion of the stacked body LMsa and the staircase portion newly formed in the stacked body LMsb and reaching the height of the upper surface of the stacked body LMsb is formed. The insulating layer 51 is also formed in an outer region of the stacked bodies LMsa and LMsb.

As illustrated in FIG. 7C, a plurality of memory holes MHb and holes HLb extending in the stacking direction of the stacked body LMsb are formed. The memory hole MHb is a portion that becomes an upper structure of the pillar PL later, and is disposed in a region that becomes the memory region MR later. The hole HLb is a portion that becomes an upper structure of the columnar portions HR later, and is disposed in a region that becomes the staircase region SR later.

The memory holes MHb and the holes HLb penetrate the stacked body LMsb and reach the upper end portions of the pillars PLc and the columnar portions HRc formed in the stacked body LMsa, respectively.

Thereafter, the sacrificial layer 26 filled in the pillars PLc and the columnar portions HRc is removed through the memory holes MHb and the holes HLb. However, in a case where the sacrificial layer 26 is a CVD-carbon layer or the like, the sacrificial layer 26 may also be collectively removed when removing the resist pattern or the like used for processing the memory hole MHb and the hole HLb.

In addition, the holes HLa and HLb connected at the upper end portion and the lower end portion are filled with the insulating layer 58 such as a silicon oxide layer to form the plurality of columnar portions HR. The columnar portion HR may be filled with the insulating layer 58 for each of the holes HLa and HLb. That is, after the holes HLa are formed in the stacked body LMsa, the insulating layer 58 is filled instead of filling the sacrificial layer 26, and after the holes HLb are formed in the stacked body LMsb, the insulating layer 58 can be further filled in the holes HLb.

In addition, a plurality of slits (not illustrated) penetrating the stacked bodies LMsa and LMsb and extending the regions that become two block regions BLK in a direction along the Y direction are formed in a portion where the upper layer side of the stacked body LMsb is processed in a staircase shape. In addition, these slits are filled with the insulating layer 57 such as a silicon oxide layer to form the plurality of plate-like portions LIy. At this time, the memory holes MHa and MHb connected at the upper end portion and the lower end portion are covered and protected with a photoresist layer or the like.

As described below, thereafter, the memory layer ME, the channel layer CN, and the core layer CR are stacked in the memory holes MHa and MHb to form a plurality of pillars PL. The memory layer ME, the channel layer CN, and the core layer CR generate stress in the stacked bodies LMsa and LMsb.

As described above, by finishing the formation of the plate-like portion LIy before these multilayer structures are formed in the memory holes MHa and MHb, for example, at the time of forming the slit to be the plate-like portion LIy, occurrence of positional displacement in each portion including the pillar PL due to the influence of the stress generated by the multilayer structure of the pillar PL is suppressed.

In addition, as described above, by forming the plate-like portion LIy at a position as far as possible in the X direction from the region where the memory holes MHa and MHb are formed, furthermore, by forming the plate-like portion LIy at a portion where the insulating layer NL on the upper layer side that becomes the select gate line SGD is processed in a staircase shape, it is possible to further suppress the positional displacement of the memory holes MHa and MHb and the like at the time of forming the slit that becomes the plate-like portion LIy and at the time of filling the insulating layer 57 into the slit.

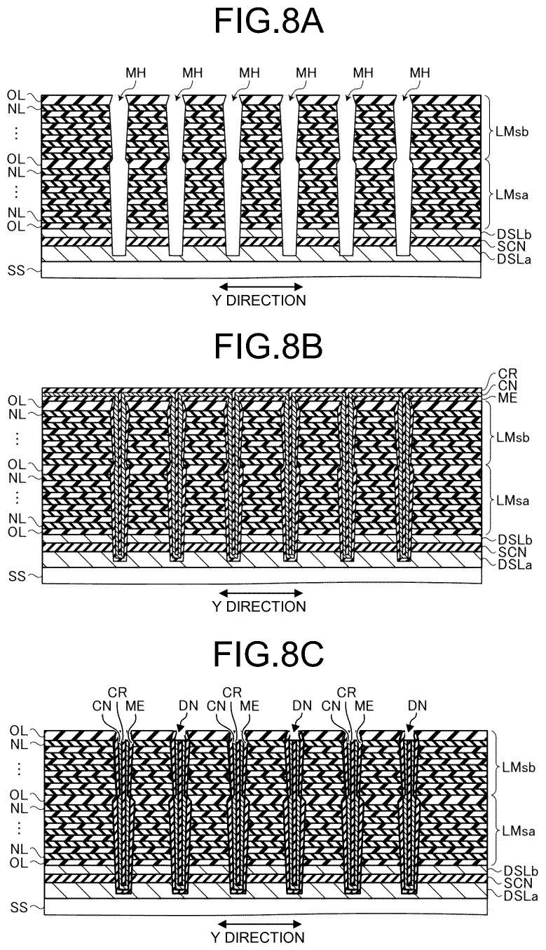

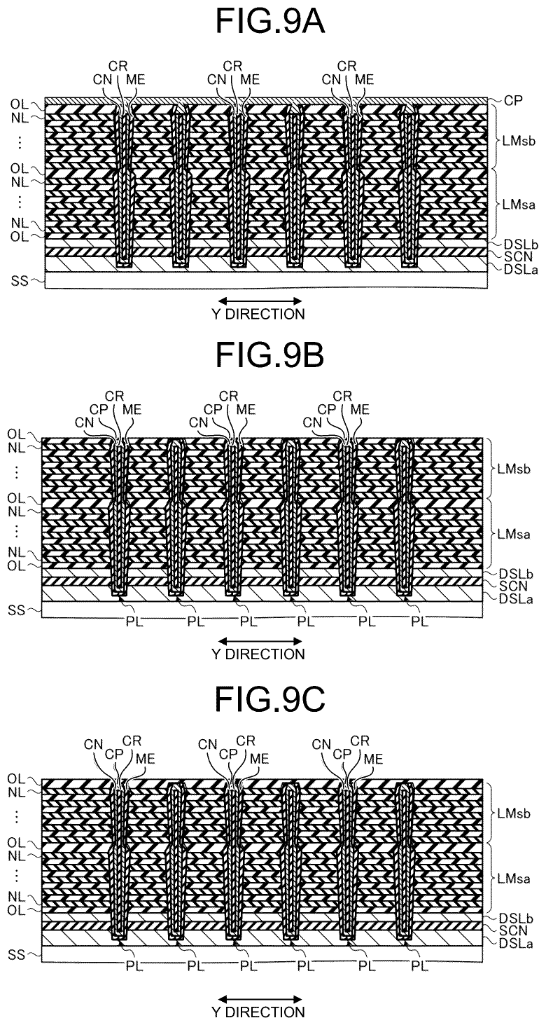

Next, a state in which the pillar PL is formed by forming a multilayer structure in the memory hole MH will be described with reference to FIGS. 8A to 9C. FIGS. 8A to 9C are cross-sectional diagrams along the Y direction of a region that becomes the memory region MR later.

As illustrated in FIG. 8A, a plurality of memory holes MH each including the memory holes MHa and MHb connected at the upper end portion and the lower end portion are formed in a region that becomes the memory region MR later.

As illustrated in FIG. 8B, a multilayer insulating layer MEb, a semiconductor layer CNb, and an insulating layer CRb are formed in this order in the memory hole MH. As a result, the multilayer insulating layer MEb and the semiconductor layer CNb are disposed on the side surface of the memory hole MH and the bottom surface where the lower source line DSLa is exposed, and the insulating layer CRb is filled in a central portion of the memory hole MH.

The multilayer insulating layer MEb is an insulating layer having a multilayer structure that becomes the memory layer ME later. The semiconductor layer CNb is a layer that becomes the channel layer CN later. The insulating layer CRb is a silicon oxide layer or the like that becomes the core layer CR later.

The multilayer insulating layer MEb, the semiconductor layer CNb, and the insulating layer CRb are also formed in this order on the upper surface of the stacked body LMsb.

As illustrated in FIG. 8C, in a region that becomes the memory region MR later, the insulating layer CRb, the semiconductor layer CNb, and the multilayer insulating layer MEb are sequentially etched back to be removed from the upper surface of the stacked body LMsb, and a recess DN from which the insulating layer CRb and the semiconductor layer CNb are removed is formed at the upper end portion of the memory hole MH.

As a result, the memory layer ME, the channel layer CN, and the core layer CR are formed in the memory hole MH in this order from the outer peripheral side.

As illustrated in FIG. 9A, in a region that becomes the memory region MR later, a semiconductor layer CPb is formed in the recess DN at the upper end portion of the memory hole MH. The semiconductor layer CPb is a layer that becomes the cap layer CP later. The semiconductor layer CPb is also formed on the upper surface of the stacked body LMsb.

As illustrated in FIG. 9B, in a region that becomes the memory region MR later, the semiconductor layer CPb on the upper surface of the stacked body LMsb is removed by CMP or the like, and the cap layer CP is formed at the upper end portion of the memory hole MH.

As illustrated in FIG. 9C, the uppermost insulating layer OL of the stacked body LMsb thinned by the above-described processing such as CMP is stacked.

As a result, the pillar PL in which the cap layer CP is buried in the uppermost insulating layer OL is formed. However, the memory layer ME covers the entire side wall of the pillar PL at this time point, and a part of the side surface of the channel layer CN is not exposed from the memory layer ME.

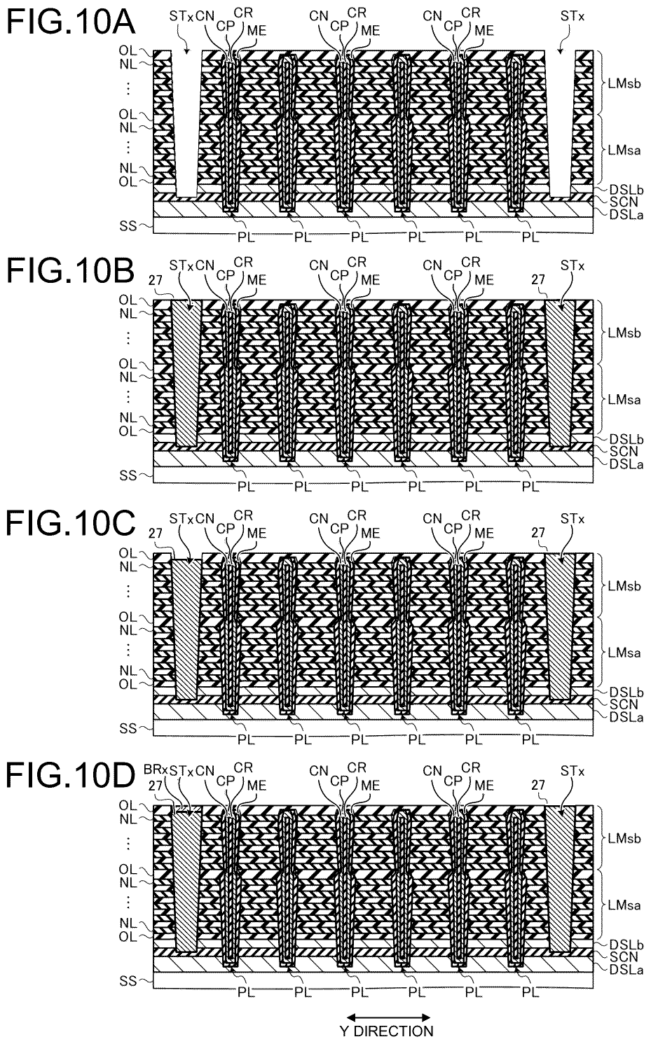

Next, a state in which the slit STx and the bridge portion BRx at the upper end portion of the slit STx are formed will be described with reference to FIGS. 10A to 10D. The slit STx is configured to become the plate-like portion LIx later. In the following drawings, a state is illustrated in which the bridge portion BRx is formed only in the slit STx on one side in the left-right direction in the plane of drawing.

Note that FIGS. 10A to 10D are cross-sectional diagrams along the Y direction of a region that becomes the memory region MR later.

As illustrated in FIG. 10A, a slit STx that penetrates the stacked bodies LMsb and LMsa and the upper source line DSLb and reaches the intermediate sacrificial layer SCN is formed.

The slit STx has a Y-direction longitudinal cross section of a tapered shape or a bowing shape, and also extends in the stacked bodies LMsa and LMsb in the direction along the X direction. Therefore, in the staircase region SR (not illustrated), the lower end portion of the slit STx reaches the intermediate insulating layer SCO.

As illustrated in FIG. 10B, the slit STx is filled with a sacrificial layer 27 such as an amorphous silicon layer.

As illustrated in FIG. 10C, a part of the sacrificial layer 27 at the upper end portion of the slit STx is removed. As a result, a plurality of recesses arranged in the X direction at predetermined intervals are formed in the upper end portion of the slit STx. The slit STx on one side in the left-right direction in the plane of drawing is a cross section of a portion where the recess is formed, and the slit STx on the other side in the left-right direction in the plane of drawing is a cross section of a portion where the recess is not formed.

As illustrated in FIG. 10D, the recesses at the upper end portion of the slit STx are filled with a polysilicon layer or the like to form a plurality of bridge portions BRx. The slit STx on one side in the left-right direction in the plane of drawing is a cross section of a portion where the bridge portion BRx is formed, and the slit STx on the other side in the left-right direction in the plane of drawing is a cross section of a portion where the bridge portion BRx is not formed.

Thereafter, the sacrificial layer 27 in the slit STx is removed. The sacrificial layer 27 is removed from the upper end portion side of the slit STx where the bridge portion BRx is not formed.

In parallel with the formation of the bridge portion BRx in the slit STx, the bridge portion BRy may be formed in the already formed plate-like portion LIy. In the case of forming the bridge portion BRy in the plate-like portion LIy, the insulating layer 57 at the upper end portion of the plate-like portion LIy is removed to form a plurality of recesses, and these recesses are filled with a polysilicon layer or the like. As a result, the bridge portion BRy is formed in the plate-like portion LIy.

However, the bridge portion BRy may be formed at another timing such as when the plate-like portion LIy is formed.

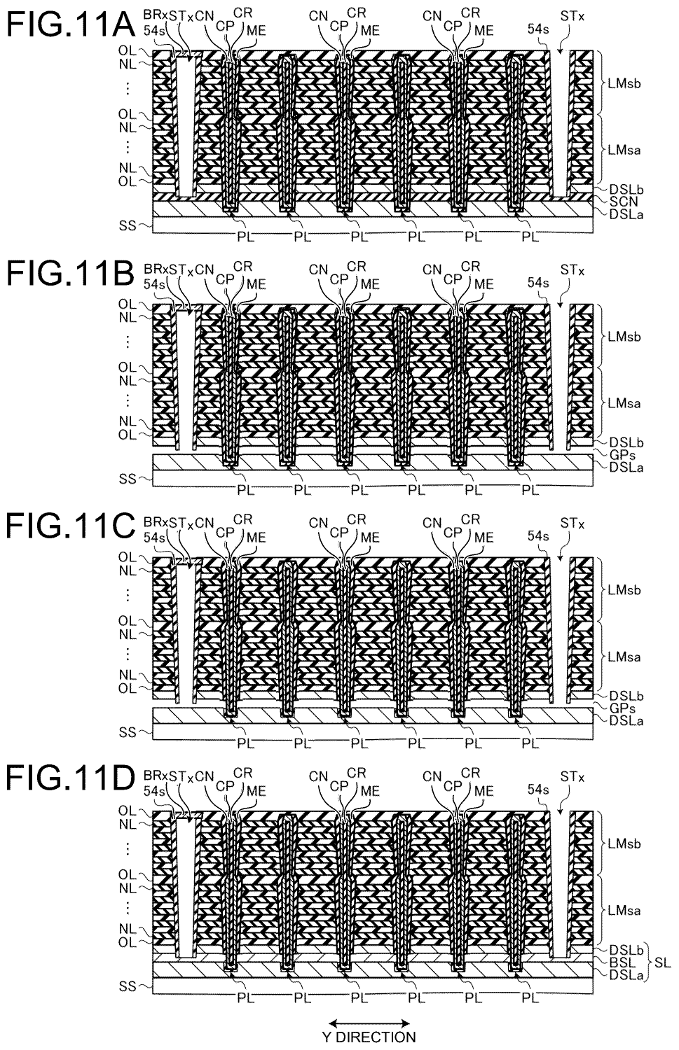

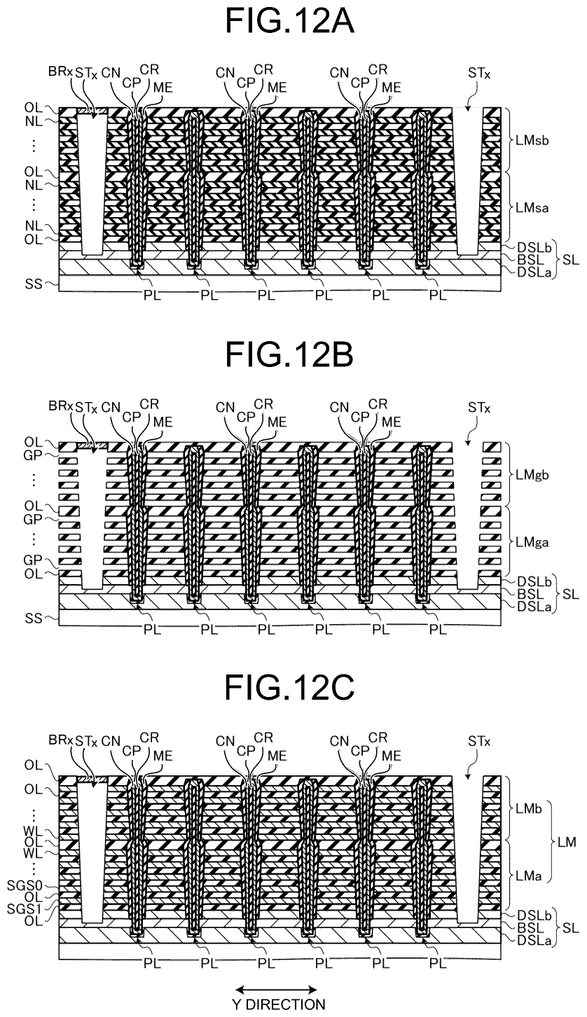

Next, a state in which the source line SL and the word line WL are formed will be described with reference to FIGS. 11A to 12C. FIGS. 11A to 12C are cross-sectional diagrams along the Y direction of a region that becomes the memory region MR later, similarly to FIGS. 10A to 10D described above.

As illustrated in FIG. 11A, an insulating layer 54s is formed on the side walls of the slit STx facing each other in the Y direction. The insulating layer 54s is formed via the upper end portion of the slit STx where the bridge portion BRx is not formed.

As illustrated in FIG. 11B, a removing solution of the intermediate sacrificial layer SCN such as hot phosphoric acid is caused to flow via the slit STx whose side walls are protected by the insulating layer 54s, and the intermediate sacrificial layer SCN sandwiched between the lower source line DSLa and the upper source line DSLb is removed.

As a result, a gap layer GPs is formed between the lower source line DSLa and the upper source line DSLb. Further, a part of the memory layer ME at the outer peripheral portion of the pillar PL is exposed in the gap layer GPs.

At this time, since the side walls of the slit STx are protected by the insulating layer 54s, even the insulating layer NL in the stacked bodies LMsa and LMsb is prevented from being removed. In addition, in the staircase region SR (not illustrated), there is no intermediate sacrificial layer SCN between the lower source line DSLa and the upper source line DSLb, and the gap layer GPs is not formed.

As illustrated in FIG. 11C, chemical solutions are caused to appropriately flow into the gap layer GPs via the slit STx, and the block insulating layer BK, the charge storage layer CT, and the tunnel insulating layer TN (see FIGS. 4B and 4C) of the memory layer ME exposed in the gap layer GPs are sequentially removed. As a result, the memory layer ME is removed from a part of the side wall of the pillar PL, and a part of the channel layer CN on the inner side is exposed in the gap layer GPs.

As illustrated in FIG. 11D, a source gas such as amorphous silicon is injected from the slit STx whose side walls are protected by the insulating layer 54s, and the gap layer GPs is filled with amorphous silicon or the like. In addition, the support substrate SS is heat-treated to polycrystallize the amorphous silicon filled in the gap layer GPs, thereby forming the intermediate source line BSL including polysilicon or the like.

As a result, a part of the channel layer CN of the pillar PL is coupled to the source line SL on the side surface via the intermediate source line BSL.

At this time, in the staircase region SR (not illustrated), the gap layer GPs is not formed between the lower source line DSLa and the upper source line DSLb. In addition, the intermediate source line BSL is not formed.

As illustrated in FIG. 12A, the insulating layer 54s on the side walls of the slit STx is temporarily removed.

As illustrated in FIG. 12B, a removing solution of the insulating layer NL such as hot phosphoric acid is caused to flow from the slit STx into the stacked bodies LMsa and LMsb to remove the insulating layers NL of the stacked bodies LMsa and LMsb. As a result, the stacked bodies LMga and LMgb having the plurality of gap layers GP from which the insulating layers NL between the insulating layers OL are removed are formed.

The stacked bodies LMga and LMgb including the plurality of gap layers GP have a fragile structure. In a region that becomes the memory region MR later, the plurality of pillars PL support such fragile stacked bodies LMga and LMgb. In addition, in a region that becomes the staircase region SR later, the plurality of columnar portions HR support such fragile stacked bodies LMga and LMgb.

Such a support structure by the pillars PL and the columnar portions HR suppresses bending of the remaining insulating layer OL and distortion or collapse of the stacked bodies LMga and LMgb.

In addition, the bridge portion BRx formed at the upper end portion of the slit STx can suppress deformation of the slit STx due to stress on both sides in the Y direction of the slit STx and occurrence of positional displacement in each portion including the pillar PL.

As illustrated in FIG. 12C, a source gas of a conductive material such as tungsten or molybdenum is injected from the slit STx into the stacked bodies LMga and LMgb, and the gap layers GP of the stacked bodies LMga and LMgb are filled with the conductive material to form the plurality of word lines WL and the like. As a result, the stacked body LM including the stacked bodies LMa and LMb in which the plurality of word lines WL and the like and the plurality of insulating layers OL are alternately stacked one layer at a time is formed.

As described above, the processing of forming the intermediate source line BSL from the intermediate sacrificial layer SCN and the processing of forming the word line WL from the insulating layer NL are also referred to as replacement processing.

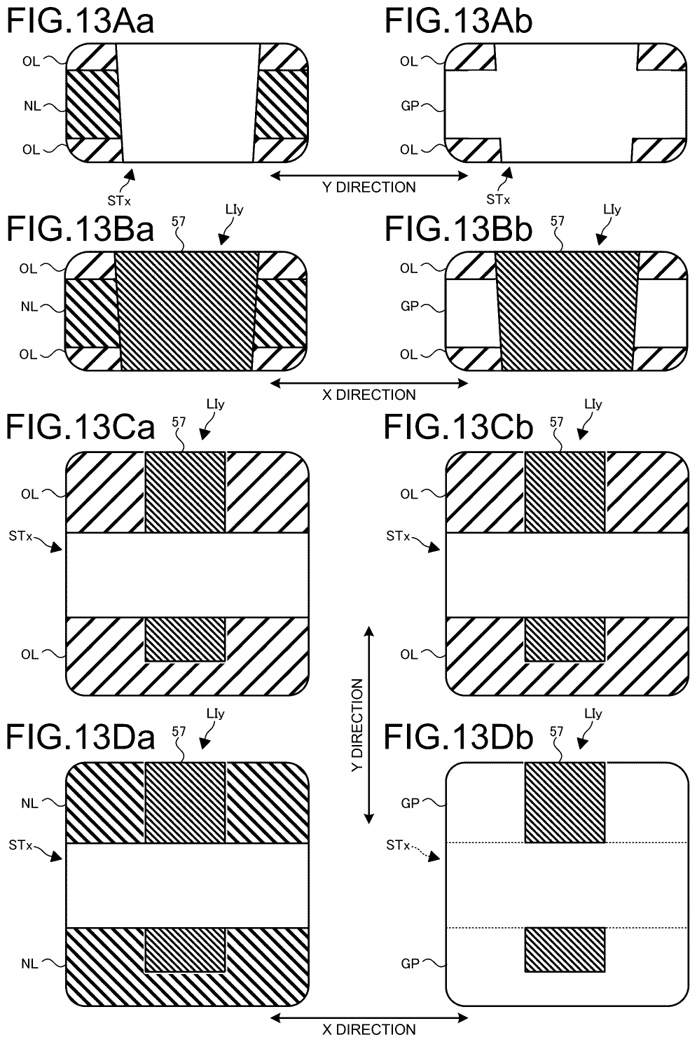

When the word line WL is formed in the gap layers GP of the stacked bodies LMga and LMgb, the above-described metal element-containing layer 55 and metal element-containing layer 25 are formed in this order in advance. Hereinafter, FIGS. 13Aa to 16Db illustrate states in the periphery of the slit STx and the plate-like portion LIy during the replacement processing of the word line WL.

FIGS. 13Aa to 16Db are cross-sectional diagrams sequentially illustrating a part of a procedure of the replacement processing of the word line WL in the semiconductor memory device 1 according to the embodiment.

In FIGS. 13Aa to 16Db, Aa and Ab are enlarged cross-sectional diagrams along the Y direction of the slit STx at a height position of an arbitrary word line WL, and Ba and Bb are enlarged cross-sectional diagrams along the X direction of the plate-like portion LIy at a height position of an arbitrary word line WL.

In addition, Ca and Cb are XY cross-sectional diagrams of the slit STx and the plate-like portion LIy at a height position of an arbitrary insulating layer OL, and Da and Db are XY cross-sectional diagrams of the slit STx and the plate-like portion LIy at a height position of an arbitrary insulating layer NL.

As illustrated in FIGS. 13Aa to 13Da, the slit STx and the plate-like portion LIy have been formed in the stacked bodies LMsa and LMsb before the replacement processing of the word lines WL and the like. As illustrated in FIGS. 13Ca and 13Da, the end portion of the plate-like portion LIy in the Y direction is divided by the slit STx extending in the direction along the X direction.

Since the slit STx and the plate-like portion LIy are disposed such that the end portions of the slit STx and the plate-like portion LIy cross each other in a cross shape, even when misalignment occurs in the slit STx formed later with respect to the plate-like portion LIy formed earlier, the end portions of the plate-like portion LIy and the slit STx can be more reliably connected to each other, and electrical separation between predetermined regions in the block region BLK can be more reliably achieved.

As illustrated in FIGS. 13Ab to 13Db, a removing solution such as hot phosphoric acid is caused to flow via the slit STx to remove the insulating layers NL in the stacked bodies LMsa and LMsb. As a result, the gap layer GP is formed in the portion from which the insulating layer NL is removed.

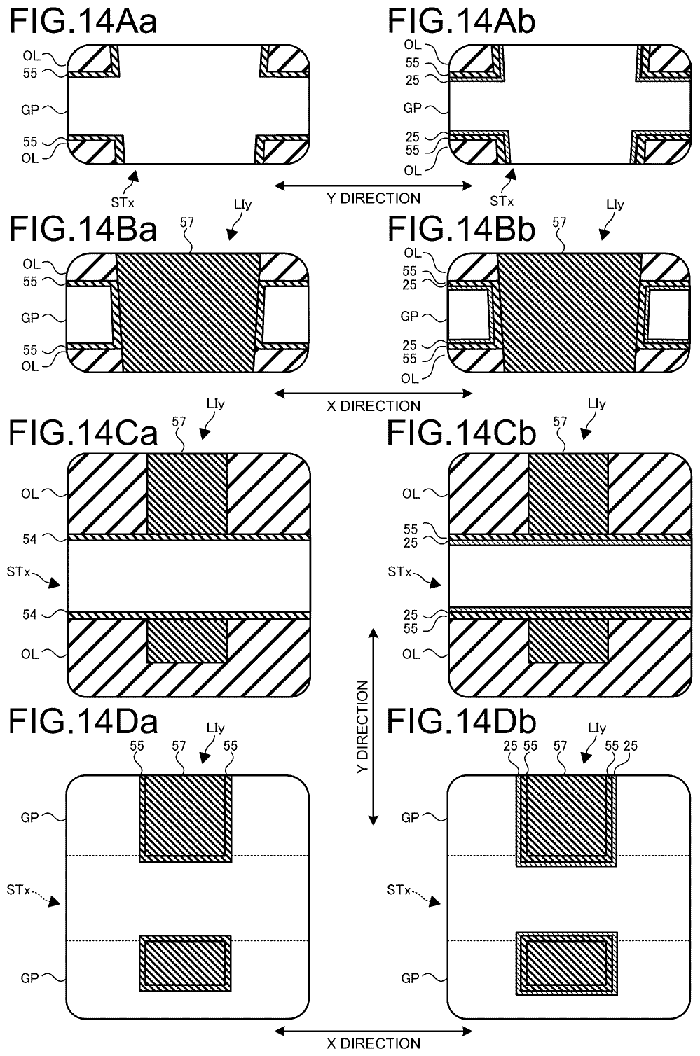

As illustrated in FIGS. 14Aa to 14Da, a source gas such as aluminum oxide is supplied to form the metal element-containing layer 55 in the gap layer GP. The metal element-containing layer 55 is formed on the upper and lower surfaces of the insulating layer OL exposed on both sides in the stacking direction of the gap layer GP.

The metal element-containing layer 55 is also formed on the end surface of the insulating layer OL facing the side surface of the slit STx in the Y direction and the side surface of the plate-like portion LIy in the X direction. At this time, the end surface of the plate-like portion LIy in the Y direction divided by the slit STx and facing the side surface of the slit STx in the Y direction is on a surface continuous with the end surface of the insulating layer OL facing the side surface of the slit STx in the Y direction at the height position of the insulating layer OL. Therefore, the metal element-containing layer 55 is also formed on the end surface of the plate-like portion LIy in the Y direction facing the side surface of the slit STx in the Y direction.

Further, the metal element-containing layer 55 is also formed on the end surface of the plate-like portion LIy in the Y direction facing the side surface of the slit STx in the Y direction at the height position of the gap layer GP. At this time, the metal element-containing layer 55 formed on the end surface of the plate-like portion LIy in the Y direction may be in a state of protruding inward the slit STx by the layer thickness of the metal element-containing layer 55, for example.

As illustrated in FIGS. 14Ab to 14Db, a source gas such as titanium, titanium nitride, tantalum, tantalum nitride, or molybdenum nitride is supplied to form the metal element-containing layer 25 in the gap layer GP. Thus, the metal element-containing layer 25 is formed in each portion in the gap layer GP via the metal element-containing layer 55.

That is, the metal element-containing layer 25 is formed on the upper and lower surfaces of the insulating layer OL exposed on both sides in the stacking direction of the gap layer GP via the metal element-containing layer 55.

The metal element-containing layer 25 is also formed on the end surface of the insulating layer OL facing the side surface of the slit STx in the Y direction and the end surface of the plate-like portion LIy in the Y direction via the metal element-containing layer 55. At this time, the metal element-containing layer 25 formed on the end surface of the plate-like portion LIy in the Y direction may be further protruded toward the inside of the slit STx, for example.

At the height position of the gap layer GP, the metal element-containing layer 25 is also formed on the side surface of the plate-like portion LIy in the X direction via the metal element-containing layer 55.

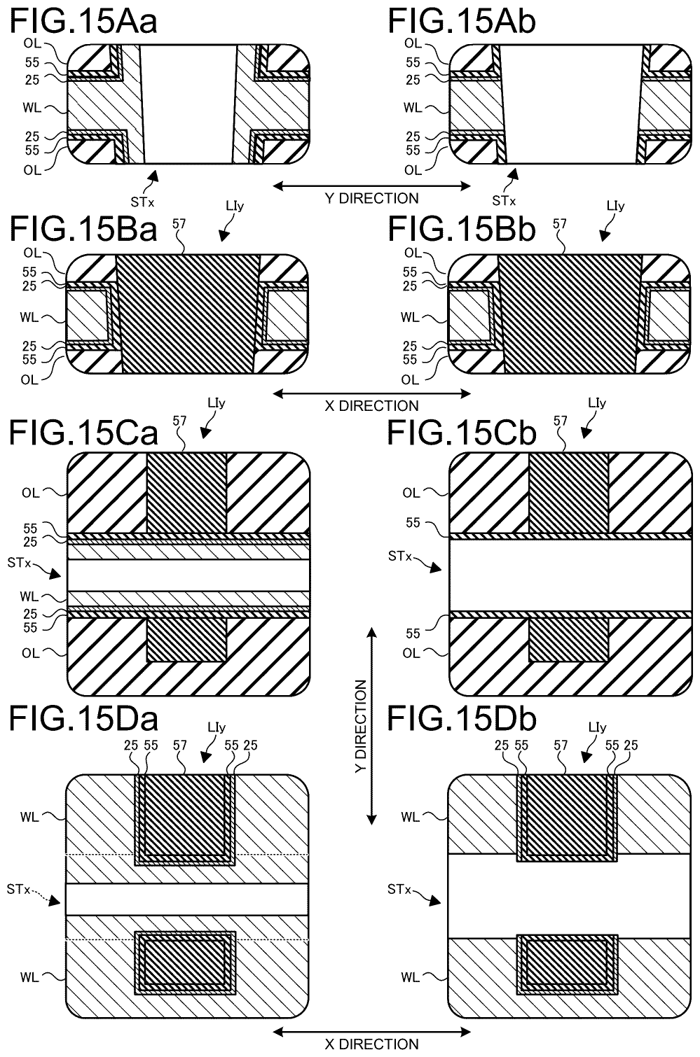

As illustrated in FIGS. 15Aa to 15Da, a source gas such as tungsten or the like is supplied into the gap layer GP in which the metal element-containing layers 55 and 25 are formed in this order, and the gap layer GP is filled with a conductive material. As a result, the word line WL and the like are formed in the gap layer GP. At this time, a tungsten layer or the like may also be formed in the slit STx.

As illustrated in FIGS. 15Ab to 15Db, the tungsten layer or the like in the slit STx are removed. In addition, the metal element-containing layer 25 formed on the end surface of the insulating layer OL facing the side surface of the slit STx in the Y direction is removed. This is to suppress conduction between the word lines WL disposed on both sides in the stacking direction of the insulating layer OL via the metal element-containing layer 25 on the end surface of the insulating layer OL. Since the metal element-containing layer 55 on the end surface of the insulating layer OL has an insulating property, it may remain without being removed.

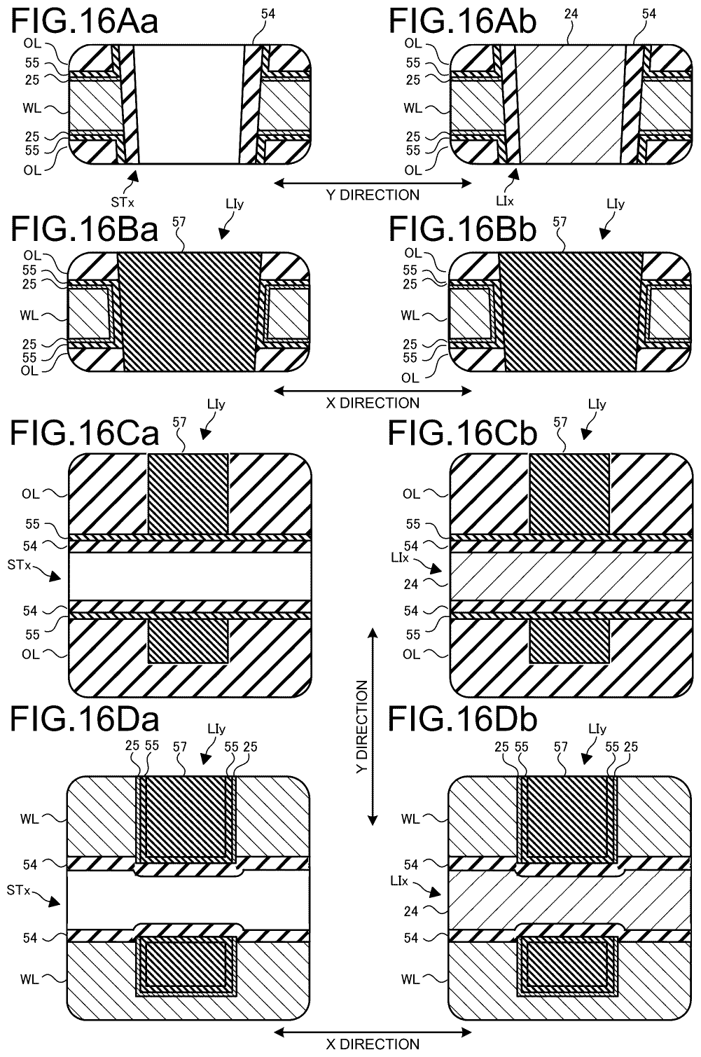

As illustrated in FIGS. 16Aa to 16Da, the insulating layer 54 covering the side walls of the slit STx is formed, and as illustrated in FIGS. 16Ab to 16Db, the inside of the slit STx is further filled with the conductive layer 24. Thus, the plate-like portion LIx is formed.

The insulating layer 54 of the plate-like portion LIx may slightly protrude into the plate-like portion LIx at the coupling portion to the plate-like portion LIy by the metal element-containing layers 25 and 55 protruding into the plate-like portion LIx.

Note that the insulating layer 54 or the like may be filled in the slit STx without forming the conductive layer 24 to form the plate-like member.

In addition, a groove penetrating one or a plurality of conductive layers including the uppermost conductive layer of the stacked body LMb is formed, and the insulating layer 56 is filled in the groove, thereby forming the separation layer SHE that partitions these conductive layers into the pattern of the select gate line SGD.

At this time, the separation layer SHE is suppressed from reaching the lower layer side of the stacked body LM beyond a target depth by the bridge portion BRy formed in the plate-like portion LIy. In addition, in a case where the end portion of the separation layer SHE in the X direction is in a positional relationship of terminating at the side surface of the plate-like portion LIy, the separation layer SHE is suppressed from being formed even in a portion where the word line WL and the like are processed in a staircase shape by the bridge portion BRy of the plate-like portion LIy. As described above, the bridge portion BRy of the plate-like portion LIy functions as a stopper layer at the time of forming the separation layer SHE.

Thereafter, a plurality of contact holes penetrating the insulating layer 51 covering the staircase region SR are formed, the insulating layer 59 covering the side walls of the contact holes is formed, and the inside of the contact holes are further filled with the conductive layer 29 to form a plurality of contacts CC.

In addition, the insulating layer 52 is formed on the upper surface of the stacked body LM and the upper surface of the insulating layer 51 covering the staircase region SR, and the plug VO coupled to the contact CC is formed through the insulating layer 52. In addition, the plug CH coupled to the pillar PL is formed through the insulating layer 52. Further, the insulating layer 53 is formed on the insulating layer 52, and the upper layer wiring MX, the bit line BL, and the like coupled to the plugs VO and CH are formed. In addition, an electrode pad and the like for electrically conducting with the peripheral circuit CBA is formed on the upper surface of the insulating layer 53.

For example, the plugs VO and CH, the upper layer wiring MX, the bit line BL, and the like may be collectively formed by using a dual damascene method or the like.

In addition, the peripheral circuit CBA is formed on the semiconductor substrate SB different from the support substrate SS on which the stacked body LM is formed, and is covered with the insulating layer 40. In the insulating layer 40, contacts, vias, wirings, and the like for drawing the peripheral circuit CBA to the surface of the insulating layer 40 are formed and coupled to the electrode pad and the like formed on the upper surface of the insulating layer 40.

Subsequently, the support substrate SS and the semiconductor substrate SB are bonded to each other by the insulating layers 50 and 40, respectively, and the electrode pads in the insulating layers 50 and 40 are coupled. Thereafter, the support substrate SS is removed to expose the source line SL, and the electrode film EL is coupled via the insulating layer 60 in which a plug PG is formed.

As described above, the semiconductor memory device 1 of the embodiment is manufactured.

### Overview

A semiconductor memory device such as a three-dimensional nonvolatile memory is configured to be able to apply a voltage to a plurality of word lines and the like by stacking a plurality of word lines and the like, forming a part of them in a staircase shape, and coupling contacts to these staircase portions. Therefore, when the number of stacked word lines and the like increases, a length of the staircase portion in the X direction, that is, a staircase length also increases.

In addition, since the staircase regions are disposed, for example, on both sides in the X direction of the stacked body, a memory region belonging to one block region is operated by the contact coupled to the staircase region on one side in the X direction. In this case, the contact is not coupled to the staircase region on the other side in the X direction, and becomes a dead space. This also facilitates an increase in the area of the staircase region in the semiconductor memory device.

According to the semiconductor memory device 1 of the embodiment, the plate-like portion LIx divides the memory region MR so as to belong to each of the block regions BLK arranged in the Y direction, and the plate-like portion LIy extends in the stacked body LM in the direction along the Y direction and the stacking direction of the stacked body LM and divides one memory region MR and the staircase region SR among the memory regions MR belonging to each of the block regions BLK arranged in the Y direction.

As described above, by electrically separating the staircase region SR on one side in the X direction of the stacked body LM from the memory region MR belonging to one block region BLK of the two block regions BLK, the staircase region SR on one side in the X direction corresponding to two block regions BLK can be allocated to the memory cell operation of the memory region MR belonging to the other block region BLK of the two block regions BLK. As a result, the area of the staircase region SR in the entire semiconductor memory device 1, that is, the staircase length can be reduced.

According to the semiconductor memory device 1 of the embodiment, the plate-like portion LIy is in contact with the side surface of the plate-like portion LIx in the Y direction via the insulating metal element-containing layer 55. In addition, the metal element-containing layer 55 continuously extends on the side surface of the plate-like portion LIx in the Y direction including the portion in contact with the plate-like portion LIy at the height position of each of the plurality of insulating layers OL of the stacked body LM.

According to the semiconductor memory device 1 of the embodiment, the plurality of word lines WL and the select gate lines SGD and SGS are in direct contact with the side surface of the plate-like portion LIx in the Y direction, and are in contact with the side surface of the plate-like portion LIy in the X direction via at least the metal element-containing layer 55. In addition, the plurality of insulating layers OL are in contact with the side surface of the plate-like portion LIx in the Y direction via the metal element-containing layer 55, and are in direct contact with the side surface of the plate-like portion LIy in the X direction.

These are all evidence that the plate-like portions LIx and LIy are respectively formed at different timings. More specifically, since the plate-like portion LIy has been formed before the replacement processing of the word line WL and the like, the metal element-containing layer 55 takes the above-described arrangement in the periphery of the plate-like portions LIx and LIy.

In order to reduce the staircase length of the entire staircase portions SPa and SPb, in electrically separating predetermined regions in the block region BLK using the plate-like portions LIx and LIy, for example, when the plate-like portions LIx and LIy are formed at the same timing, the stacked bodies LMsa and LMsb are divided at a plurality of places, and there is a possibility that the amount of positional displacement between the configurations formed in the stacked bodies LMsa and LMsb increases.

By forming the plate-like portions LIx and LIy at different timings as in the semiconductor memory device 1 of the embodiment, it is possible to reduce the number of places where the stacked bodies LMsa and LMsb are divided at a time, and it is possible to suppress positional displacement between the respective configurations in the stacked bodies LMsa and LMsb.

According to the semiconductor memory device 1 of the embodiment, the plurality of contacts CC are disposed in the staircase portions SPa and SPb arranged in the X direction with the memory regions MR adjacent in the Y direction, and are coupled to the plurality of memory cells MC included in the memory region MR which is disposed side by side in the X direction with the staircase portion SPa.

More specifically, when the staircase portions SPa and SPb disposed in the staircase regions SR at both end portions of two block regions BLK adjacent to each other in the Y direction, on one side in the X direction, the contacts CC of the staircase portions Spa and SPb are used for the operation of the memory cells MC in the memory region MR belonging to one of the two block regions BLK, and, on the other side in the X direction, they are used for the operation of the memory cells MC in the memory region MR belonging to the other of the two block regions BLK. As a result, it is possible to suppress the occurrence of the dead space in the staircase region SR, and in principle, the area of the staircase region SR in the semiconductor memory device 1 and the staircase lengths of the staircase portions SPa and SPb can be reduced to about ½ of a case where the configuration of the embodiment is not adopted.

### Modification

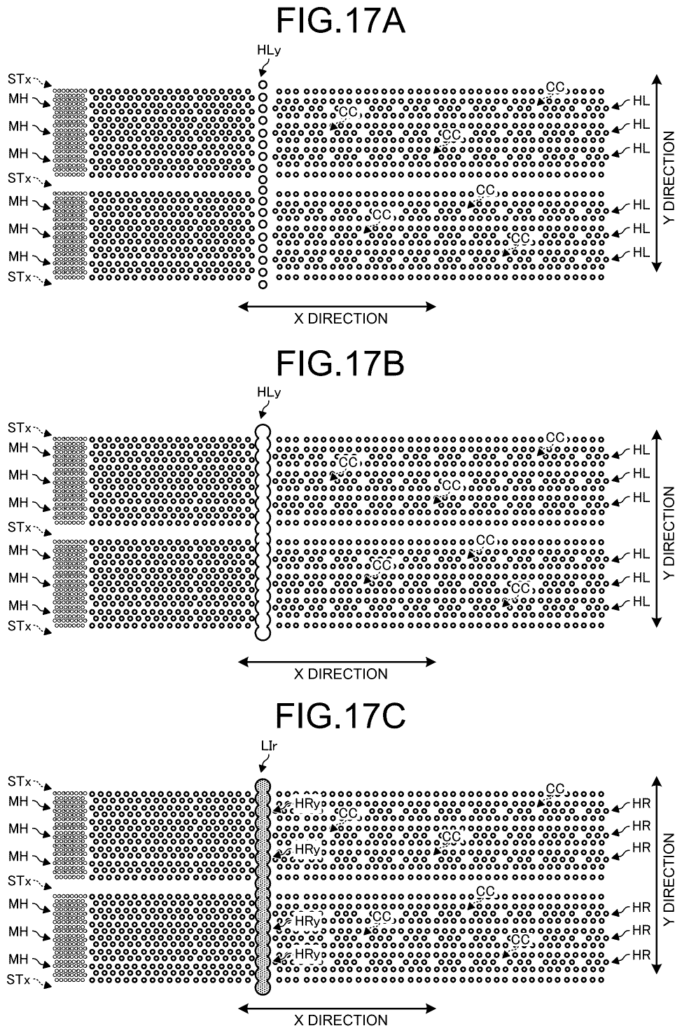

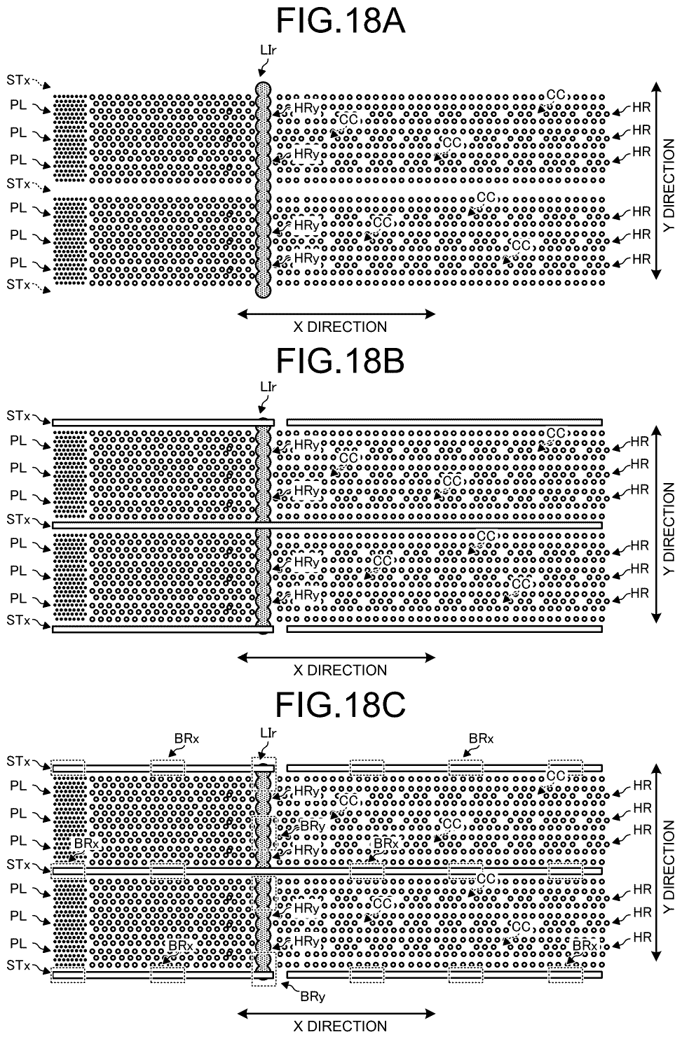

Next, a semiconductor memory device according to a modification of the embodiment will be described with reference to FIGS. 17A to 18C. In the semiconductor memory device of the modification, a method for forming a plate-like portion LIr extending in the Y direction is different from that of the plate-like portion LIy of the above-described embodiment.

In the following drawings, the same reference numerals are given to the same configurations as those of the above-described embodiment, and the description thereof may be omitted.

FIGS. 17A to 18C are cross-sectional diagrams sequentially illustrating a part of a procedure of the method for forming the plate-like portions LIx and LIr in the semiconductor memory device according to the modification of the embodiment. More specifically, FIGS. 17A to 18C are XY cross-sectional diagrams at a height position of an arbitrary insulating layer NL.

As illustrated in FIG. 17A, it is assumed that a staircase shape, a plurality of memory holes MH, and a plurality of holes HL have been formed in the stacked bodies LMsa and LMsb before replacement processing. The memory holes MH and the holes HL have a periodic arrangement such as a staggered arrangement.

However, these memory holes MH and holes HL are not disposed in the region where the slit STx is formed later and the region where the contact CC coupled to the word line WL and the select gate line SGS is formed. Note that since the region illustrated in FIG. 17A is a portion that becomes the staircase portion SPb later, a space where the contact CC is formed is not provided in a portion where the insulating layer NL on the upper layer side of the stacked body LMsb is processed in a staircase shape.

In addition, a plurality of holes HLy having a larger diameter than the other holes HL are disposed side by side in the direction along the Y direction between a portion where the insulating layer NL on the upper layer side, that becomes the select gate line SGD later, is processed in a staircase shape and a portion where the insulating layer NL on the lower layer side, that becomes the word line WL and the like later, is processed in a staircase shape.

At this time, the diameter of the plurality of holes HLy is preferably set within a range that can be collectively formed with the plurality of memory holes MH and holes HL. In addition, the formation positions of the holes HL and HLy are preferably adjusted so that the plurality of holes HL and HLy are periodically disposed as a whole. This facilitates collective formation of the plurality of memory holes MH and the holes HL and HLy.

As illustrated in FIG. 17B, the diameter of the plurality of holes HLy is enlarged by a wet treatment or the like. At this time, the plurality of holes HLy may be enlarged in diameter at least at the height positions of the plurality of insulating layers NL, whereby the plurality of holes HLy are connected to each other in the Y direction at least at the height positions of the plurality of insulating layers NL.

However, the diameter of the plurality of holes HLy may be enlarged over the entirety in the stacking direction, and the entire side surfaces of the holes HLy in the Y direction may be connected to each other.

As illustrated in FIG. 17C, the plurality of holes HLy connected to each other in the Y direction are filled with an insulating layer such as a silicon oxide layer to form the plate-like portion LIr to which the plurality of columnar portions HRy are connected. At this time, the insulating layer can also be filled in the plurality of holes HL to form the plurality of columnar portions HR.

Note that during the processing illustrated in FIG. 17C, the plurality of memory holes MH are protected by a photoresist layer or the like covering them.

As illustrated in FIG. 18A, the memory layer ME, the channel layer CN, the core layer CR, and the like are sequentially formed in the memory hole MH to form a plurality of pillars PL.

As illustrated in FIG. 18B, a plurality of slits STx extending in the direction along the X direction in the region between the plurality of pillars PL and the columnar portions HR are formed. At this time, for example, the slit STx at the central portion in the plane of drawing extends in the X direction from the region between the plurality of pillars PL to the region between the plurality of columnar portions HR while dividing the substantially central portion of the plate-like portion LIr in the Y direction. In addition, the upper and lower slits STx in the plane of drawing extend in the region between the plurality of pillars PL in the direction along the X direction, intersect with both end portions of the plate-like portion LIr in the Y direction, and then further extend in the region between the plurality of columnar portions HR in the direction along the X direction with a gap.

As illustrated in FIG. 18C, a plurality of bridge portions BRx are formed at the upper end portion of the slit STx at predetermined intervals in the X direction. In addition, a plurality of bridge portions BRy are formed at the upper end portion of the plate-like portion LIr at predetermined intervals in the Y direction.

The bridge portion BRy of the plate-like portion LIr is not formed at the same timing as the bridge portion BRx of the plate-like portion LIx, and may be formed, for example, at the time of forming the plate-like portion LIr.

The subsequent processing is performed, for example, similarly to the processing of FIG. 11A and subsequent processing of the above-described embodiment. Thus, the plate-like portions LIx and LIr are formed by the method of the modification.

According to the semiconductor memory device of the modification, the plate-like portion LIr extends in the stacked body LM in the stacking direction, and includes the plurality of columnar portions HRy connected in the Y direction at least at the height positions of the plurality of word lines WL and the select gate lines SGD and SGS. As a result, many processing at the time of forming the plate-like portion LIr can be collectively performed with the forming processing of the columnar portions HR, and the plate-like portion LIr can be formed more easily.

According to the semiconductor memory device of the modification, the plurality of columnar portions HR and HRy are periodically disposed as a whole when viewed from the stacking direction of the stacked body LM. By the columnar portions HR and HRy disposed in this manner, processing can be performed with high accuracy when collectively forming the columnar portions HR and HRy.

### Other Modifications

In the above-described embodiment and modification, the two-row staircase, the three-row staircase, or the like in which the terrace portion configured by the word lines WL and the like ascend one layer at a time from one side to the other side in the Y direction of the staircase portions SPa and SPb adjacent in the Y direction and forming a pair has been mainly described. However, the configurations of the staircase portions SPa and SPb are not limited thereto.

For example, in each of the individual staircase portions SPa and SPb having a multi-row staircase structure of three or more rows, the word lines WL and the like configuring the terrace portions belonging to the row of the central portion in the Y direction may be the word lines WL lower than the word lines WL and the like of the terrace portions of the other rows.

That is, for example, in the three-row staircase structure, when the positions of the terrace portions in the X direction included in the staircases of the first to third rows arranged in the Y direction are equal, the number of layers of the word lines WL and the like included in the stacking direction in the terrace portion of the first row>the number of layers of the word lines WL and the like included in the stacking direction in the terrace portion of the second row<the number of layers of the word lines WL and the like included in the stacking direction in the terrace portion of the third row may be satisfied.

Furthermore, for example, in the four-row staircase structure, when the positions of the terrace portions in the X direction included in the staircases of the first to fourth rows arranged in the Y direction are equal, the number of layers of the word lines WL and the like included in the stacking direction in the terrace portion of the first row>the number of layers of the word lines WL and the like included in the stacking direction in the terrace portion of the second row, and the number of layers of the word lines WL and the like included in the stacking direction in the terrace portion of the third row<the number of layers of the word lines WL and the like included in the stacking direction in the terrace portion of the fourth row may be satisfied.

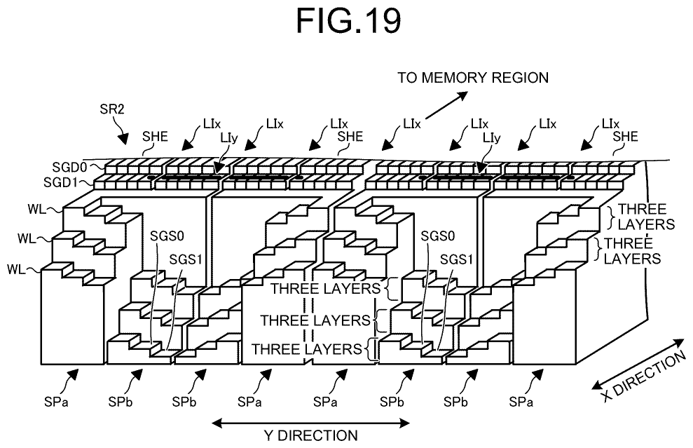

Furthermore, as another example, the terrace portions of the word lines WL and the select gate lines SGS included in the stacked body LMa may be disposed on one of a pair of the staircase portions SPa and SPb among the stacked bodies LMa and LMb which are the lower and upper structures of the stacked body LM, and the terrace portions of the word lines WL included in the stacked body LMb may be disposed on the other of the pair of the staircase portions SPa and SPb. Such an example is illustrated in FIG. 19.

FIG. 19 is a schematic perspective diagram of a staircase region SR2 included on one side in the X direction in a stacked body of a semiconductor memory device according to another modification of the embodiment. Note that also in FIG. 19, a description will be given using a three-row staircase as an example.

As illustrated in FIG. 19, in the staircase portion SPb out of the staircase portions SPa and SPb adjacent in the Y direction, the terrace portions of the word lines WL and the select gate lines SGS included in the stacked body LMa are disposed. In addition, in the staircase portion SPa out of the staircase portions SPa and SPb, the terrace portions of the word lines WL included in the stacked body LMb are disposed.

Also in this case, the terrace portions of the word lines WL or the select gate lines SGS ascend from the staircase portion SPb side to the staircase portion SPa side in the Y direction. In the staircase portion SPa or the staircase portion SPb, these terrace portions ascend one layer at a time. On the other hand, at the boundary portion between the staircase portions SPa and SPb, the total number of layers of the word lines WL and the select gate lines SGS included in the stacking direction is different between the terrace portion of the staircase portion SPb and the terrace portion of the staircase portion SPa by the total number of layers of the word lines WL and the select gate lines SGS having the terrace portions in the staircase portion SPb.

In addition, in the example of FIG. 19, in each pair of the staircase portions SPa and SPb adjacent to each other in the Y direction, the terrace portions of the word lines WL and the like ascend three layers at a time in the X direction toward the memory region MR.

Even with such a configuration, all the word lines WL and the select gate lines SGS included in the stacked body LM have terrace portions in any one of the staircase portions SPa and SPb, and the plurality of word lines WL and the select gate lines SGD and SGS in the stacked body LM can be drawn out by the pair of these staircase portions SPa and SPb.

In the embodiment and the modification described above, the plate-like portion LIy extending in the direction along the Y direction extends across the two block regions BLK to divide the memory region MR and the staircase region SR in these block regions BLK. However, the number of block regions BLK divided by one plate-like portion LIy is not limited thereto. For example, one plate-like portion LIy may extend in the direction along the Y direction so as to divide one block region BLK. Even in such a configuration, it is possible to draw out the plurality of word lines WL and the select gate lines SGD and SGS in the stacked body LM by using the staircase portions SPa and SPb disposed in the staircase regions SR at both end portions of the block region BLK corresponding to the two block regions BLK as a pair.

In the embodiment and the modification described above, the bridge portions BRx and BRy are provided at the upper end portions of the plate-like portions LIx, LIy, and LIr, respectively. However, at least one of the plate-like portions LIx, LIy, and LIr may also have a bridge portion at a height position between the stacked bodies LMa and LMb.

In order to form the bridge portion also at the height position between the upper and lower ends of the plate-like portion LIr, the bridge portion can be formed at the upper end portion of the hole after forming the hole of the lower structure of the columnar portions HRy in the stacked body LMsa, and the bridge portion can be formed at the upper end portion of the hole after forming the hole of the upper structure of the columnar portions HRy in the stacked body LMsb.

In order to form the bridge portion also at the height position between the upper and lower ends of the plate-like portions LIx and LIy, the slit STx may be formed for each of the stacked bodies LMa and LMb. That is, a slit penetrating the stacked body LMsa is formed at a predetermined timing, and the bridge portion is formed at the upper end portion of the slit. In addition, after the formation of the stacked body LMsb, a slit penetrating the stacked body LMsb is formed at a predetermined timing, and a bridge portion is formed at the upper end portion of the slit.

At this time, for example, the memory hole MHa of the stacked body LMa may be separately formed, and the hole HLa and the slit that becomes the lower structure of the plate-like portions LIx and LIy may be collectively formed.

In the embodiment and the modification described above, the reach depths of the plate-like portions LIx and LIy in the source line SL are substantially the same, but the reach depths of the plate-like portions LIx and LIy may be different from each other. In the plate-like portion LIx and the plate-like portion LIy, since the plate-like portion LIx has a lower aspect ratio, the reach depth of the plate-like portion LIx may be deeper than that of the plate-like portion LIy.

In addition, in the embodiment and the modification described above, the stacked body LM having a two-tier structure is provided. However, the configuration of the stacked body LM may be one-tier structure or three-tier structure or more.

Further, in the embodiment and the modification described above, the pillar PL is coupled to the source line SL on the side surface of the channel layer CN, but the present invention is not limited thereto. For example, the pillar may be configured to be coupled to the source line at the lower end portion of the channel layer by removing the memory layer on the bottom surface of the pillar.

In the embodiment and the modification described above, the peripheral circuit CBA is disposed above the stacked body LM. However, the peripheral circuit may be disposed below the stacked body or in the same layer as the stacked body.

In a case where the peripheral circuit is disposed below the stacked body, for example, the source line and the stacked body can be formed on an insulating layer of a semiconductor substrate having the peripheral circuit covered with the insulating layer. When the peripheral circuit is disposed on the same layer as the stacked body, the stacked body can be formed at a position different from the peripheral circuit on the semiconductor substrate on which the peripheral circuit is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers are stacked apart from each other, and first and second staircase regions in which the plurality of conductive layers are processed in a staircase shape are disposed at both end portions in a first direction intersecting a stacking direction of the plurality of conductive layers with a memory region interposed therebetween;
a first plate-like portion that extends in the stacked body in the first direction and the stacking direction and divides the memory region into first and second sub-memory regions adjacent in a second direction intersecting both the stacking direction and the first direction; and
a second plate-like portion that extends in the stacked body in the second direction and the stacking direction and divides the first sub-memory region and the first staircase region, wherein
the second plate-like portion is coupled to a side surface of the first plate-like portion in the second direction via an insulating metal-containing layer.

2. The semiconductor memory device according to claim 1, wherein
in the stacked body, the plurality of conductive layers and a plurality of insulating layers are alternately stacked one by one, and
at a height position of each of the plurality of insulating layers, the metal-containing layer continuously extends on the side surface in the second direction of the first plate-like portion, including a portion coupled to the second plate-like portion.

3. The semiconductor memory device according to claim 1, wherein
the plurality of conductive layers include a first group and a second group having different stacking positions in the stacked body,
the first staircase region includes:
a first sub-staircase region disposed side by side with the first sub-memory region in the first direction, in which conductive layers belonging to the first group among the plurality of conductive layers are processed in a staircase shape, and
a second sub-staircase region disposed side by side with the second sub-memory region in the first direction, in which conductive layers belonging to the second group among the plurality of conductive layers are processed in a staircase shape, and
in the first and second sub-staircase regions, a plurality of first contacts electrically coupled to a plurality of memory cells included in the second sub-memory region are disposed.

4. The semiconductor memory device according to claim 3, further comprising:
a separation layer that penetrates conductive layers belonging to a third group stacked on an upper layer side of the conductive layers of the first and second groups, extends in the memory region in the first direction, and divides the conductive layers belonging to the third group in the second direction in the first and second sub-memory regions, wherein
the second plate-like portion is disposed in a terrace portion provided such that a lowermost conductive layer among the conductive layers belonging to the third group through which the separation layer penetrates does not overlap an upper conductive layer in the stacking direction, between the first sub-memory region and the first sub-staircase region.

5. The semiconductor memory device according to claim 4, wherein
a plurality of second contacts are disposed in a portion where the conductive layers belonging to the third group are processed in a staircase shape, between the second sub-memory region and the second sub-staircase region.

6. The semiconductor memory device according to claim 1, further comprising:
a third plate-like portion that extends in the stacked body in the second direction and the stacking direction and divides the second sub-memory region and the second staircase region, wherein
the third plate-like portion is coupled to a side surface of the first plate-like portion in the second direction via the metal-containing layer.

7. The semiconductor memory device according to claim 6, wherein
in the stacked body, the plurality of conductive layers and a plurality of insulating layers are alternately stacked one by one, and
at a height position of each of the plurality of insulating layers, the metal-containing layer continuously extends on the side surface in the second direction of the first plate-like portion, including a portion coupled to the third plate-like portion.

8. The semiconductor memory device according to claim 6, wherein
the plurality of conductive layers include a third group and a fourth group having different stacking positions in the stacked body,
the second staircase region includes:
a third sub-staircase region disposed side by side with the first sub-memory region in the first direction, in which conductive layers belonging to the third group among the plurality of conductive layers are processed in a staircase shape, and
a fourth sub-staircase region disposed side by side with the second sub-memory region in the first direction, in which conductive layers belonging to the fourth group among the plurality of conductive layers are processed in a staircase shape, and
in the third and fourth sub-staircase regions, a plurality of third contacts electrically coupled to a plurality of memory cells included in the first sub-memory region are disposed.

9. The semiconductor memory device according to claim 1, wherein
the second plate-like portion includes a plurality of first columnar portions extending in the stacked body in the stacking direction and being connected in the second direction at least at height positions of the plurality of conductive layers.

10. The semiconductor memory device according to claim 9, wherein
in the first staircase region, a plurality of second columnar portions extending in the stacked body in the stacking direction are dispersedly disposed, and
the plurality of first and second columnar portions are periodically disposed as a whole when viewed in the stacking direction.

11. A semiconductor memory device comprising:
a stacked body in which a plurality of conductive layers are stacked apart from each other, and first and second staircase regions in which the plurality of conductive layers are processed in a staircase shape are disposed at both end portions in a first direction intersecting a stacking direction of the plurality of conductive layers with a memory region interposed therebetween;
a first plate-like portion that extends in the stacked body in the first direction and the stacking direction and divides the memory region into first and second sub-memory regions adjacent in a second direction intersecting both the stacking direction and the first direction; and
a second plate-like portion that extends in the stacked body in the second direction and the stacking direction and divides the first sub-memory region and the first staircase region, wherein
the plurality of conductive layers are
directly coupled to a side surface of the first plate-like portion in the second direction, and
coupled to a side surface of the second plate-like portion in the first direction via at least a first metal-containing layer.

12. The semiconductor memory device according to claim 11, wherein
in the stacked body, the plurality of conductive layers and a plurality of insulating layers are alternately stacked one by one,
the plurality of conductive layers are coupled to the side surface of the second plate-like portion in the first direction via the first metal-containing layer disposed on a side of the plurality of conductive layers and a second metal-containing layer disposed on a side of the second plate-like portion, and
the plurality of insulating layers are
coupled to the side surface of the first plate-like portion in the second direction via the first metal-containing layer not via the second metal-containing layer, and
directly coupled to the side surface of the second plate-like portion in the first direction.

13. The semiconductor memory device according to claim 11, wherein
the plurality of conductive layers include a first group and a second group having different stacking positions in the stacked body,
the first staircase region includes:
a first sub-staircase region disposed side by side with the first sub-memory region in the first direction, in which conductive layers belonging to the first group among the plurality of conductive layers are processed in a staircase shape, and
a second sub-staircase region disposed side by side with the second sub-memory region in the first direction, in which conductive layers belonging to the second group among the plurality of conductive layers are processed in a staircase shape, and
in the first and second sub-staircase regions, a plurality of first contacts electrically coupled to a plurality of memory cells included in the second sub-memory region are disposed.

14. The semiconductor memory device according to claim 13, further comprising:
a separation layer that penetrates conductive layers belonging to a third group stacked on an upper layer side of the conductive layers of the first and second groups, extends in the memory region in the first direction, and divides the conductive layers belonging to the third group in the second direction in the first and second sub-memory regions, wherein
the second plate-like portion is disposed in a terrace portion provided such that a lowermost conductive layer among the conductive layers belonging to the third group through which the separation layer penetrates does not overlap an upper conductive layer in the stacking direction, between the first sub-memory region and the first sub-staircase region.

15. The semiconductor memory device according to claim 14, wherein
a plurality of second contacts are disposed in a portion where the conductive layers belonging to the third group are processed in a staircase shape, between the second sub-memory region and the second sub-staircase region.

16. The semiconductor memory device according to claim 11, further comprising:
a third plate-like portion that extends in the stacked body in the second direction and the stacking direction and divides the second sub-memory region and the second staircase region, wherein
the plurality of conductive layers are coupled to a side surface of the third plate-like portion in the first direction via at least the first metal-containing layer.

17. The semiconductor memory device according to claim 16, wherein
in the stacked body, the plurality of conductive layers and a plurality of insulating layers are alternately stacked one by one,
the plurality of conductive layers are coupled to the side surface of the third plate-like portion in the first direction via the first metal-containing layer disposed on a side of the plurality of conductive layers and a second metal-containing layer disposed on a side of the third plate-like portion, and
the plurality of insulating layers are
coupled to the side surface of the first plate-like portion in the second direction via the first metal-containing layer not via the second metal-containing layer, and
directly coupled to the side surface of the third plate-like portion in the first direction.

18. The semiconductor memory device according to claim 16, wherein
the plurality of conductive layers include a third group and a fourth group having different stacking positions in the stacked body,
the second staircase region includes:
a third sub-staircase region disposed side by side with the first sub-memory region in the first direction, in which conductive layers belonging to the third group among the plurality of conductive layers are processed in a staircase shape, and
a fourth sub-staircase region disposed side by side with the second sub-memory region in the first direction, in which conductive layers belonging to the fourth group among the plurality of conductive layers are processed in a staircase shape, and
in the third and fourth sub-staircase regions, a plurality of third contacts electrically coupled to a plurality of memory cells included in the first sub-memory region are disposed.

19. The semiconductor memory device according to claim 11, wherein
the second plate-like portion is coupled to the side surface of the first plate-like portion in the second direction via the first metal-containing layer.

20. The semiconductor memory device according to claim 19, wherein
in the stacked body, the plurality of conductive layers and a plurality of insulating layers are alternately stacked one by one, and
the first metal-containing layer continuously extends on the side surface of the first plate-like portion in the second direction, including a portion coupled to the second plate-like portion at a height position of each of the plurality of insulating layers.
